(19) United States
(12) Patent Application Publication
(10) Pub. No.: US 2025/0110403 A1
(43) Pub. Date: Apr. 3, 2025

(54) PHOTOSENSITIVE COMPOSITION CONTAINING PFAS-FREE POLYCYCLOOLEFINIC POLYMERS AND SEMICONDUCTOR DEVICE MADE THEREOF

(71) Applicants: PROMERUS, LLC, AKRON, OH (US); SUMITOMO BAKELITE CO., LTD, TOKYO (JP)

(72) Inventors: TAKANOBU MASUDA, TOKYO (JP); KENTO NISHIDA, TOKYO (JP); AKIHIKO OTOGURO, TOKYO (JP); TOSHIHARU KUBOYAMA, TOKYO (JP); EIKO TOMIYAMA, TOKYO (JP); HIROMICHI SUGIYAMA, TOKYO (JP); J. ALEX NIEMIEC, AKRON, OH (US); DOUG SKILSKYJ, AKRON, OH (US)

(73) Assignees: PROMERUS, LLC, AKRON, OH (US); SUMITOMO BAKELITE CO., LTD, TOKYO (JP)

(21) Appl. No.: 18/898,989

(22) Filed: Sep. 27, 2024

Related U.S. Application Data
(60) Provisional application No. 63/564,344, filed on Mar. 12, 2024.

(30) Foreign Application Priority Data
Sep. 29, 2023 (JP) 2023-170440

(51) Int. Cl. G03F 7/039; G03F 7/004; H01L 23/00; H01L 25/065

(52) U.S. Cl. CPC G03F 7/039; G03F 7/0045; H01L 24/29; H01L 24/32; H01L 25/0657; H01L 2224/2919; H01L 2224/32145; H01L 2225/0651; H01L 2225/06562

(57) ABSTRACT

The present invention relates to photosensitive compositions containing PFAS-free polynorbornene (PNB) copolymers and terpolymers in combination with certain additives that are useful for forming microelectronic and/or optoelectronic devices and assemblies thereof, and more specifically to compositions encompassing PFAS-free PNBs and certain multifunctional crosslinking agents, and two or more phenolic compounds which are resistant to thermo-oxidative chain degradation and exhibit improved mechanical properties.

### CROSS REFERENCE TO RELATED APPLICATIONS

This application claims the benefit of U.S. Provisional Application No. 63/564,344, filed Mar. 12, 2024; and benefit of priority of Japanese Patent Application No. JP2023-170440, filed Sep. 29, 2023; both of which are incorporated herein by reference in their entirety.

### TECHNICAL FIELD

Embodiments in accordance with the present invention relate generally to PFAS-free compositions containing either a copolymer or a terpolymer derived from a variety of functionalized norbornene monomers, in combination with a few additives that are useful for forming microelectronic and/or optoelectronic devices and assemblies thereof, and more specifically to a composition containing either a copolymer or a terpolymer of functionalized norbornene repeating units in which first repeat unit contains a polyether functionalized end group, a second repeat unit contains a phenolic group and a third repeat unit contains a carboxylic acid group, where such compositions exhibit improved dissolution properties and improved thermal, mechanical and opto-electronic properties.

### BACKGROUND

Organic polymer materials are increasingly being used in the microelectronics and optoelectronics industries for a variety of applications. For example, the uses for such organic polymer materials include interlevel dielectrics, redistribution layers, stress buffer layers, leveling or planarization layers, alpha-particle barriers, and passivation layers for microelectronic and optoelectronic devices. Where such organic polymer materials are photosensitive, thus self-imageable, and therefore, offer additional advantage of reducing the number of processing steps required for the use of such layers and structures made therefrom. Additionally, such organic polymer materials enable the direct adhesive bonding of devices and device components to form various structures. Such devices include microelectromechanical systems (MEMS) and microoptoelectromechanical systems (MOEMS).

While polyimide (PI), polybenzoxazole (PBO) and benzocyclobutene (BCB) compositions have been materials of choice for many of the aforementioned applications due to their generally good thermal stability and mechanical strength, each of the above materials are either formed during curing from precursors that react to modify the polymer's backbone (PI and PBO) or to form such backbone (BCB) and thus generally require special handling conditions during curing to remove by-products that are formed during such curing and/or to exclude oxygen or water vapor that can prevent such curing. Additionally, the curing of such materials often requires process temperatures in excess of 250° C. (and as high as 400° C. for some materials), resulting in excessive and undesirable process costs. Therefore, such materials can be problematic for some applications, e.g., redistribution and interlevel dielectric layers as well as direct adhesive bonding of a transparent cover over image sensing arrays.

Therefore, it is believed that it would be advantageous to provide a material, useful for forming the aforementioned structures, that exhibits thermal stability and mechanical strength equivalent to the known PI, PBO, and BCB compositions, where such a material has a fully formed polymer backbone that allows for curing at temperatures of 200° C. or lower. Further, such an advantageous material should be tailorable in its characteristics to provide appropriate levels or values of stress, modulus, dielectric constant, elongation to break and permeability to water vapor for the application for which it is intended. Still further, it would be advantageous for such a material to be self-imageable. In addition, several of the presently available compositions may not be suitable in certain of the applications as they do not exhibit the required dissolution rate (DR) properties, including desirable resolution and photospeed, as further described in detail below.

A few of the above-mentioned problems have been successfully overcome by the polynorbornene based photosensitive compositions disclosed in U.S. Pat. No. 11,537,045 and a few of the art recited therein. However, many of the polynorbornenes employed therein contain at least one norbornene repeat unit containing perfluoroalkyl group. Recently, it has been observed that several of the per- or polyfluoroalkyl substances (PFAS) are environmentally persistent (i.e., they do not degrade readily in the environment) and may be linked to harmful health effects in humans and animals. Accordingly, there is an increased interest in developing PFAS-free compositions for use in electronic applications especially as flexible materials that provide much needed adhesive strength and mechanical strength, particularly, die shear strength for fabricating a variety of micro-optoelectronic devices, such as display devices, among others.

Accordingly, there is still a need to develop photo imageable PFAS-free compositions which feature desirable thermal properties, dissolution rate, bond adhesion, and most importantly integration into all involved process steps involved in the microelectronic industry.

### BRIEF DESCRIPTION OF THE DRAWINGS

Embodiments in accordance with the present invention are described below with reference to the following accompanying figures and/or images. Where drawings are provided, it will be drawings which are simplified portions of various embodiments of this invention and are provided for illustrative purposes only.

FIG. 1 is a sectional view showing an embodiment of a semiconductor device of the present invention.

### DETAILED DESCRIPTION

Embodiments in accordance with the present invention are directed to self-imageable compositions that encompass a PFAS-free polymer derived from norbornene monomers as described herein and the films, layers, structures, devices or assemblies that can be formed using such compositions. Some of such embodiments encompass self-imageable compositions which can provide positive-tone images, after image-wise exposure of a film formed thereof, followed by development of such images, using an aqueous base developer solution.

Further, the embodiments as described fully herein can routinely provide films of desirable thickness in the range of about 2 to 5 microns (μm) or greater and images demonstrating aspect ratios in excess of 1:2 for isolated line/trench resolution in such films. The films, layers, and structures formed from the polymer embodiments of the present invention being useful for, among other things, interlevel dielectrics, redistribution layers, stress buffer layers, leveling or planarization layers, alpha-particle barriers for both microelectronic and optoelectronic devices and the assemblies formed thereof, as well as adhesive bonding to form chip-stacks and to fixably attach transparent covers over image sensing arrays.

The terms as used herein have the following meanings:

Unless otherwise indicated, all numbers, values and/or expressions referring to quantities of ingredients, reaction conditions, polymer compositions, and formulations used herein are to be understood as modified in all instances by the term “about” as such numbers are inherently approximations that are reflective of, among other things, the various uncertainties of measurement encountered in obtaining such values. Further, where a numerical range is disclosed herein, such range is continuous, and includes unless otherwise indicated, every value from the minimum value to and including the maximum value of such range. Still further, where such a range refers to integers, unless otherwise indicated, every integer from the minimum value to and including the maximum value is included. In addition, where multiple ranges are provided to describe a feature or characteristic, such ranges can be combined to further describe such a feature or characteristic.

As used herein, the articles “a,” “an,” and “the” include plural referents unless otherwise expressly and unequivocally limited to one referent.

It will be understood that, as used herein, the phrase “microelectronic device” is inclusive of a “micro-optoelectronic device” and an “optoelectronic device”. Thus, reference to microelectronic devices or a microelectronic device assemblies are inclusive of optoelectronic devices and micro-optoelectronic devices as well as assemblies thereof.

Similarly, microelectromechanical systems (MEMS) include microoptoelectro-mechanical systems (MOEMS).

It will be understood that the term “redistribution layer (RDL)” refers to an electrical signal routing insulation material which features desirable and reliable properties. The term RDL may also be used interchangeably to describe buffer coating layers, such as for example, a stress relief or buffer layer between the solder ball and fragile low-K structure.

As used herein, the term “polymer” will be understood to mean a molecule that encompasses a backbone of one or more distinct types of repeating units (the smallest constitutional unit of the polymer) and is inclusive of, in addition to the polymer itself, residues from initiators, catalysts, and other elements attendant to the forming of such a polymer, where such residues are generally understood as not being covalently incorporated thereto, but maybe covalently bound to the front or back end of the polymeric chain as in certain catalyst initiated polymerization. Further, such residues and other elements, while normally removed during post polymerization purification processes, are typically mixed or co-mingled with the polymer such that some small amount generally remains with the polymer when it is transferred between vessels or between solvents or dispersion media.

As used herein, the term “polymer composition” is meant to include at least one synthesized polymer, as well as materials added after the forming of the polymer(s) to provide or modify specific properties of such composition. Exemplary materials that can be added include, but are not limited to, solvents, photoactive compounds (PAC), dissolution rate inhibitors, dissolution rate enhancers, dissolution promoters, crosslinking moieties, reactive diluents, antioxidants, adhesion promoters, and plasticizers.

As used herein, the term “modulus” is understood to mean the ratio of stress to strain and unless otherwise indicated, refers to the Young's Modulus or Tensile Modulus measured in the linear elastic region of the stress-strain curve. Modulus values are generally measured in accordance with ASTM method DI708-95. Films having a low modulus are understood to also have low internal stress.

The term “photodefinable” refers to the characteristic of a material or composition of materials, such as a polymer or polymer composition in accordance with embodiments of the present invention, to be formed into, in and of itself, a patterned layer or a structure. In alternate language, a “photodefinable layer” does not require the use of another material layer formed thereover, for example, a photoresist layer, to form the aforementioned patterned layer or structure. It will be further understood that a polymer composition having such a characteristic is generally employed in a pattern forming scheme to form a patterned film/layer or structure. It will be noted that such a scheme incorporates an “imagewise exposure” of the photodefinable material or layer formed therefrom. Such imagewise exposure being taken to mean an exposure to actinic radiation of selected portions of the layer, where non-selected portions are protected from such exposure to actinic radiation.

As used herein, the term “self-imageable compositions” will be understood to mean a material that is photodefinable and can thus provide patterned layers and/or structures after direct image-wise exposure of a film formed thereof followed by development of such images in the film using an appropriate developer.

As used herein, “hydrocarbyl” refers to a radical or a group that contains only carbon and hydrogen atoms, non-limiting examples being alkyl, cycloalkyl, aryl, aralkyl, alkaryl, and alkenyl. The term “halohydrocarbyl” refers to a hydrocarbyl group where at least one hydrogen atom has been replaced by a halogen atom. The term perhalocarbyl refers to a hydrocarbyl group where all hydrogens have been replaced by halogens. The term “heterohydrocarbyl” refers to any of the previously described hydrocarbyls, halohydrocarbyls, and perhalohydrocarbyls where at least one carbon atom of the carbon chain is replaced with an N, O, S, Si or P atom.

As used herein, the symbol “ [symbol] ” denotes a position at which the bonding takes place with another repeat unit or another atom or molecule or group or moiety as appropriate with the structure of the group as shown.

As used herein, the expression “alkyl” means a saturated, straight-chain or branched-chain hydrocarbon substituent having the specified number of carbon atoms. Particular alkyl groups are methyl, ethyl, n-propyl, isopropyl, tert-butyl, and so on. Derived expressions such as “alkoxy”, “thioalkyl”, “alkoxyalkyl”, “hydroxyalkyl”, “alkylcarbonyl”, “alkoxycarbonylalkyl”, “alkoxycarbonyl”, “diphenylalkyl”, “phenylalkyl”, “phenylcarboxyalkyl” and “phenoxyalkyl” are to be construed accordingly.

As used herein, the expression “cycloalkyl” includes all of the known cyclic aliphatic radicals. Representative examples of “cycloalkyl” includes without any limitation cyclopropyl, cyclobutyl, cyclopentyl, cyclohexyl, cycloheptyl, cyclooctyl, and the like. Derived expressions such as “cycloalkoxy”, “cycloalkylalkyl”, “cycloalkylaryl”, “cycloalkylcarbonyl” are to be construed accordingly.

As used herein, the expression “alkenyl” means a non-cyclic, straight or branched hydrocarbon chain having the specified number of carbon atoms and containing at least one carbon-carbon double bond, and includes ethenyl and straight-chained or branched propenyl, butenyl, pentenyl and hexenyl groups. Similarly, the expression “alkynyl” means a non-cyclic, straight or branched hydrocarbon chain having the specified number of carbon atoms and containing at least one carbon-carbon triple bond, and includes ethynyl and propynyl, and straight-chained or branched butynyl, pentynyl and hexynyl groups.

As used herein the expression “acyl” shall have the same meaning as “alkanoyl”, which can also be represented structurally as “R—CO—,” where R is an “alkyl” as defined herein having the specified number of carbon atoms. Additionally, “alkylcarbonyl” shall mean same as acyl as defined herein. Specifically, “(C₁-C₄)acyl” shall mean formyl, acetyl or ethanoyl, propanoyl, n-butanoyl, etc. Derived expressions such as “acyloxy” and “acyloxyalkyl” are to be construed accordingly.

As used herein, the expression “perfluoroalkyl” means that all of the hydrogen atoms in said alkyl group are replaced with fluorine atoms. Illustrative examples include trifluoromethyl and pentafluoroethyl, and straight-chained or branched heptafluoropropyl, nonafluorobutyl, undecafluoropentyl and tridecafluorohexyl groups. Derived expression, “perfluoroalkoxy”, is to be construed accordingly.

As used herein, the expression “aryl” means substituted or unsubstituted phenyl or naphthyl. Specific examples of substituted phenyl or naphthyl include o-, p-, m-tolyl, 1,2-, 1,3-, 1,4-xylyl, 1-methylnaphthyl, 2-methylnaphthyl, etc. “Substituted phenyl” or “substituted naphthyl” also include any of the possible substituents as further defined herein or one known in the art. Derived expression, “arylsulfonyl,” is to be construed accordingly.

The expressions “arylalkyl” or “aralkyl” are used interchangeably herein, and specifically “(C₆-C₁₀)aryl(C₁-C₄)alkyl” or “(C₇-C₁₄)aralkyl” means that the (C₆-C₁₀)aryl as defined herein is further attached to (C₁-C₄)alkyl as defined herein. Representative examples include benzyl, phenylethyl, 2-phenylpropyl, 1-naphthylmethyl, 2-naphthylmethyl, and the like.

“Halogen” or “halo” means chloro, fluoro, bromo, and iodo.

In a broad sense, the term “substituted” is contemplated to include all permissible substituents of organic compounds. In a few of the specific embodiments as disclosed herein, the term “substituted” means substituted with one or more substituents independently selected from the group consisting of (C₁-C₆)alkyl, (C₂-C₆)alkenyl, (C₁-C₆)perfluoroalkyl, phenyl, hydroxy, —CO₂H, an ester, an amide, (C₁-C₆)alkoxy, (C₁-C₆)thioalkyl, (C₁-C₆)perfluoroalkoxy, —NH₂, Cl, Br, I, F, —NH-lower alkyl, and —N(lower alkyl)₂. However, any of the other suitable substituents known to one skilled in the art can also be used in these embodiments.

It will be understood that the terms “dielectric” and “insulating” are used interchangeably herein. Thus, reference to an insulating material or layer is inclusive of a dielectric material or layer and vice versa.

As used herein, the terms “polycycloolefin”, “poly(cyclic) olefin”, and “polynorbornene-type” are interchangeably used to refer to polymers formed from addition polymerizable monomers, the repeating units in the resulting polymers or the compositions that encompass such polymers, where repeating units of such resulting polymers encompass at least one norbornene-type moiety. The simplest norbornene-type polymerizable monomer encompassed by embodiments in accordance with the present invention is norbornene itself, bicyclo[2.2.1]hept-2-ene, as shown below:

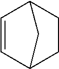

It has now been found that certain of the polymers as described herein in combination with a variety of additives when used in the composition of this invention remarkably improves the performance of the compositions in forming a thick or thin film having utility in a variety of applications including but not limited to mechanical, electrical, or electromechanical devices, including chip-stacking applications, as a redistribution layer (RDL) and in dam structures of a complementary metal oxide semiconductor (CMOS) image sensor and various other MEMS and MOEMS containing devices.

Thus, in accordance with the practice of this invention there is provided a photosensitive composition comprising:
a) a polymer having a first repeating unit of formula (IA) derived from a monomer of formula (I):

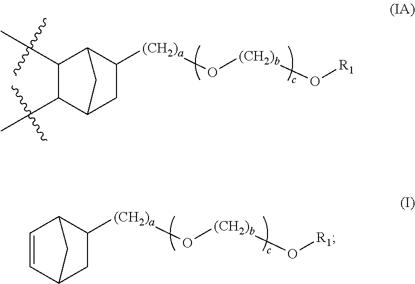

and
a second repeating unit of formula (IIA) derived from a monomer of formula (II):

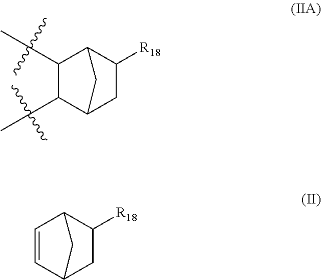

wherein:
[symbol] represents a position at which the bonding takes place with another repeat unit;
a is an integer from 0 to 3 inclusive;
b is an integer from 1 to 4 inclusive;
c is an integer from 1 to 4 inclusive;
R₁ is selected from the group consisting of hydrogen, methyl, ethyl, n-propyl, i-propyl and n-butyl, wherein one or more of the methylene group, i.e., CH₂ group may optionally be substituted independently with a group selected from the group consisting of (C₁-C₄)alkyl, phenyl and phenyl(C₁-C₄)alkyl;
R₁₈ is —(CH₂)ᵥ—CO₂R₁₉ where v is an integer from 0 to 4, and
R₁₉ is hydrogen or C₁-C₄alkyl;
b) a photo active compound containing a diazo-quinone moiety of formula (A):

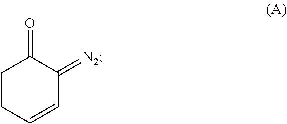

c) a multifunctional crosslinking agent selected from the group consisting of:
   a compound of the formula (IV):

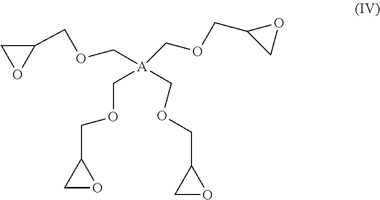

and
a compound of the formula (V):

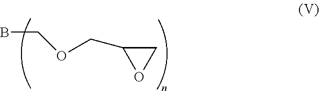

wherein:
n is an integer from 3 to 8;
A is selected from the group consisting of C, CH—(CR₂)_{d}—CH and substituted or unsubstituted aryl, where d is an integer from 0 to 4 and R is selected from the group consisting of hydrogen, methyl, ethyl, n-propyl, i-propyl and n-butyl;
B is selected from the group consisting of substituted or unsubstituted (C₁-C₆)alkyl, (C₂-C₆)alkylene and substituted or unsubstituted aryl;
wherein said substituents are selected from the group consisting of halogen, methyl, ethyl, linear or branched (C₃-C₆)alkyl, (C₃-C₈)cycloalkyl, (C₆-C₁₀)aryl, (C₇-C₁₂)aralkyl, methoxy, ethoxy, linear or branched (C₃-C₆)alkyloxy, (C₃-C₈)cycloalkyloxy, (C₆-C₁₀)aryloxy and (C₇-C₁₂)aralkyloxy;
d) a phenolic compound selected from the group consisting of:

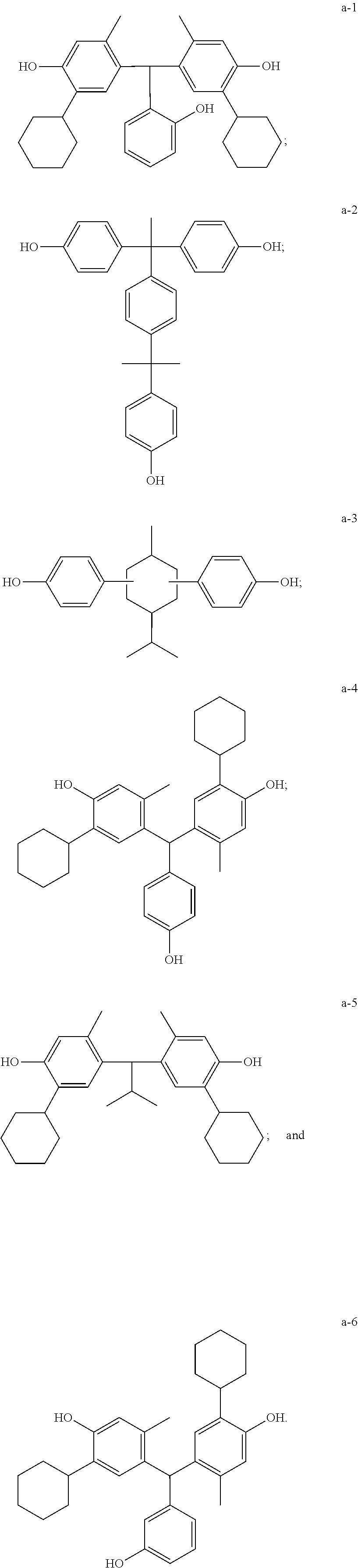

The composition of this invention can further comprise a polymer comprising a third repeating unit of formula (IIIA) derived from a monomer of formula (III):

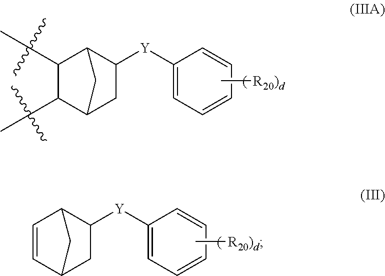

wherein,
d is an integer from 1 to 4;
Y is a bond or CH₂;
each R₂₀ is independently selected from the group consisting of hydroxy, methoxy and acetoxy.

In addition, the composition of this invention can further comprise one or more phenolic compounds. Generally, it has now been found that one or more compounds of formula (VIA) or compounds of formula (VIB) or a combination thereof can be used in the composition of this invention which provides additional benefits.

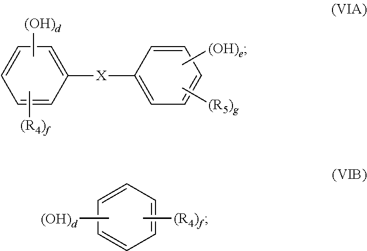

wherein d and e are integers from 1 to 4;
f and g are integers from 0 to 4;
X is selected from the group consisting of: a bond, —O—, —OCH₂O—, —OCH₂CH₂O—, —S—, —S—S—, —SO₂— and a group of formula —CR₂R₃—; where R₂ and R₃ are the same or different and independently of each other selected from hydrogen, methyl, ethyl, linear or branched C₃-C₆alkyl, C₃-C₈cycloalkyl, C₆-C₁₀aryl and C₇-C₁₂aralkyl; or
R₂ and R₃ taken together with the carbon atom to which they are attached form a 5 to 8 membered substituted or unsubstituted carbocyclic ring where said substituents are selected from C₁-C₈alkyl;
R₄ and R₅ are the same or different and independently of each other selected from hydrogen, methyl, ethyl, linear or branched (C₃-C₆)alkyl, (C₃-C₈)cycloalkyl, (C₆-C₁₀)aryl and (C₇-C₁₂)aralkyl.

In some embodiments, the polymer of this invention contains a repeat unit of formula (IIA), in which R₁₈ is generally hydroxy or methoxy. However, some embodiments may contain a polymer having a mixture of repeat units of formula (IIA) in which portions of the repeat units of formula (IIA) have R₁₈ as hydroxy and other portions of repeat units of formula (IIA) have R₁₈ as acetoxy. Accordingly, it should be understood that all such variations are part of this invention as readily appreciated by one of skill in the art.

Similarly, in some embodiments, the polymer of this invention contains a repeat unit of formula (IIIA), in which R₂₀ is generally hydrogen. However, some embodiments may contain a polymer having a mixture of repeat units of formula (IIIA) in which portions of the repeat units of formula (IIIA) have R₂₀ as hydrogen and other portions of repeat units of formula (IIIA) have R₂₀ as (C₁-C₄)alkyl. Accordingly, it should be understood that all such variations are part of this invention as readily appreciated by one of skill in the art.

Non-limiting examples of monomers that can be employed to form the first repeat unit of the polymer of this invention include the following:

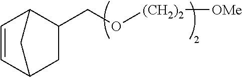

5-((2-(2-methoxyethoxy)ethoxy)methyl)bicyclo[2.2.1]hept-2-ene, also referred to as trioxanonanenorbornene (NBTON);

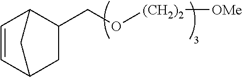

1-(bicyclo[2.2.1]hept-5-en-2-yl)-2,5,8,11-tetraoxadodecane, also referred to as tetraoxadodecanenorbomene (NBTODD);

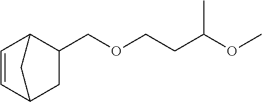

5-(3-methoxybutoxy)methyl-2-norbornene (NB-3-MBM);

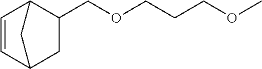

5-(3-methoxypropanoxy)methyl-2-norbornene (NB-3-MPM);

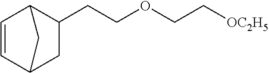 [SMILES: CCOCCOCCC1CC2C=CC1C2]

5-(2-(2-ethoxyethoxy)ethyl)bicyclo[2.2.1]hept-2-ene; and

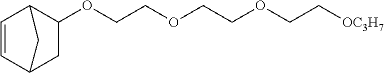

5-(2-(2-(2-propoxyethoxy)ethoxy)ethoxy)bicyclo[2.2.1]hept-2-ene.

Non-limiting examples of monomers that can be employed to form the second repeat unit of the polymer of this invention include the following:

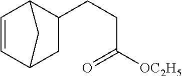

ethyl 3-(bicyclo[2.2.1]hept-2-en-2-yl)propanoate (EPEsNB);

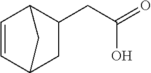 [SMILES: O=C(O)CC1CC2C=CC1C2]

3-(bicyclo[2.2.1]hept-5-en-2-yl)acetic acid (NBMeCOOH);

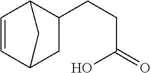 [SMILES: O=C(O)CCC1CC2C=CC1C2]

norbornenylpropanoic acid (NBEtCOOH); and

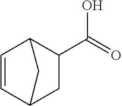

bicyclo[2.2.1]hept-5-ene-2-carboxylic acid (Acid NB).

Non-limiting examples of monomers that can be employed to form the third repeat unit, if present, of the polymer of this invention include the following:

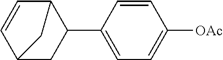

4-(bicyclo[2.2.1]hept-5-en-2-yl)phenyl acetate (PhOAcNB);

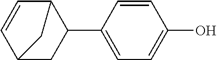 [SMILES: Oc1ccc(C2CC3C=CC2C3)cc1]

4-(bicyclo[2.2.1]hept-5-en-2-yl)phenol (PhOHNB);

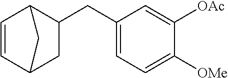 [SMILES: COc1ccc(CC2CC3C=CC2C3)cc1OC(C)=O]

4-norbornenylmethyl-2-methoxyphenol acetate (EugOAcNB); and

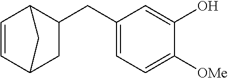 [SMILES: COc1ccc(CC2CC3C=CC2C3)cc1O]

4-(bicyclo[2.2.1]hept-4-en-2-ylmethyl)-2-methoxyphenol (EugOHNB).

It should however be noted that the photosensitive composition of this invention can be made by employing a polymer derived from any two or three monomers listed above, which are within the scope of the monomers of formulae (I) to (II) and (III), if present. Further any amounts of the monomers of formulae (I) to (III) can be employed to form either the copolymer or terpolymer which produces the intended benefit and for the intended purpose as further described below. Accordingly, all such conceivable monomer ratios are part of this invention.

In some embodiments of this invention the photosensitive composition of this invention is made by using either a copolymer or a terpolymer containing any of two or three monomers as described herein.

In general, the polymer embodiments in accordance with the present invention encompass the above described one or more of the first, second and third distinct type of repeating units, if needed, as it will be seen below, other repeating units encompassed by such polymer embodiments are selected to provide properties to such polymer embodiments that are appropriate and desirable for the use for which such embodiments are directed, thus such polymer embodiments are tailorable to a variety of specific applications.

For example, polymer embodiments generally require at least one repeating unit directed to providing imageability. Thus, distinct types of repeating units, represented by structural formula (IIA), can include R₁₈ being a carboxylic acid containing pendent group. However, any of the other functional group which would result in an acidic pendent moiety can also be used instead. Carboxylic acid pendent groups are generally useful for participating in a reaction with appropriately selected additives, or other repeating units that can lead to fix a positive-tone image via post develop thermal crosslinking. Thus, similar pendent groups including but not limited to phenolic, sulfonic and other functional groups may also work in this embodiment of the invention. It should further be noted that one of skill in the art readily appreciates that such polymer compositions containing acidic pendent groups can be made post polymerization by utilizing appropriate monomers. For example, a polymer containing NBEtCOOH monomer repeat units can generally be made by first forming the polymer using EPEsNB, and then hydrolyzing the ester function in the resulting polymer using any of the known procedures in the art. Thus, certain residual amount of the ester monomeric repeat units may always be present in the polymer employed herein. That is, when a polymer containing repeat units such as NBEtCOOH is used, such polymer may still contain some monomeric repeat units derived from EPEsNB, i.e., the starting monomer.

It should further be noted that more than one distinct types each of monomers of formulae (I) to (III) can be employed in any molar ratios to form the polymer of this invention. That is, one or more monomers of monomer of formula (I) can be employed with one or more monomers of formula (II) and if needed one or more monomers of formula (III) to form the polymers of this invention. Thus, the polymers of this invention generally incorporate repeating units of formula (IA) from about 1 mole percent to about 98 mole percent. The remaining repeat units are being derived from a combination of one or more repeat units of formulae (IIA) and (IIIA). Accordingly, in some embodiments a copolymer containing any combinations of monomeric repeat units of formula (IA) and (IIA) in which the molar ratios of the repeat units can be 99:1 to 1:99, more specifically, 5:95, 10:90, 15:85, 20:80, 25:75, 30:70, 35:65, 40:60, 45:55, 50:50, 55:45, 60:60, 65:35, 70:30, 75:25, 80:20, 85:95, 90:10, 95:5, and the like. Similarly, in some other embodiments a terpolymer containing any combinations of monomeric repeat units of formula (IA), (IIA) and (IIIA) in which the molar ratios of the repeat units can be 40:30:30, 40:40:20, 50:20:30, 50:25:25, 50:30:20, 50:40:10, 50:45:5, 60:20:20, and the like. In some other embodiments examples of such monomer molar ratio of (I):(II):(III) employed to form the polymer can range from 1:1:98 to 99:1:0 to 1:98:1 respectively, where the molar ratios of the repeat units of formulae (IA):(IIA):(IIIA) is essentially of the same order. In some other embodiments such ratios include 30:40:30, 40:30:30, 40:40:20, 40:45:15, 40:50:10, 45:40:15, 45:35:20, 50:35:15, 50:40:10 or any such combination.

In general, it has now been found that a polymer containing the monomer repeat unit having an acidic pendent group (generally of formula (IIA)) advantageously provides certain beneficial effect for the photosensitive composition of this invention. Thus, in some embodiments of this invention, the polymer used in the photosensitive composition of this invention contains a monomer repeat unit containing the acid pendent group from about 10 to 80 mol %, and in some other embodiments from 20 to 70 mol %. In some other embodiments the molar percent of monomer repeat units of formula (IA) in the polymer may be from about 0 to 80 mol %, from about 10 to 80 mol % and in some other embodiments from about 20 to 70 mol %. In some other embodiments the molar percent of monomer repeat units of formula (IIIA) in the polymer may be from about 5 to 80 mol %, from about 10 to 80 mol % and in some other embodiments from about 20 to 70 mol %.

The polymers employed in the photosensitive compositions according to this invention generally exhibit a weight average molecular weight (M_{w}) of at least about 30,000. In another embodiment, the polymer employed in this invention has a M_{w} of at least about 40,000. In yet another embodiment, the polymer has a M_{w} of at least about 50,000. Further, in an embodiment of this invention the polymer employed herein exhibits a weight average molecular weight of from 30,000 to 100,000, or from 40,000 to 80,000 or from 50,000 to 75,000. The weight average molecular weight (M_{w}) and the number average molecular weight (Mₙ) are generally determined by gel permeation chromatography (GPC) using polystyrene calibration standards. However, any of the other known methods can also be used to determine M_{w} and Mₙ. From this the polydispersity index (PDI) of the polymer can also be determined (M_{w}/Mₙ).

In another aspect of this invention, the photosensitive composition of this invention contains a photoactive compound which generally contains a photo active diazo-quinone moiety. Such photoactive compounds (PACs) are known to undergo photo-rearrangement when subjected to actinic (or electromagnetic) radiation of suitable wavelength, such as for example 254, 365, 405, or 436 nm depending upon the nature of the PAC employed the wavelength of the radiation can be modified by employing suitable light source. For example, in some embodiments of this invention the PACs employed contain one or more of the diazo-quinone moiety represented by formula (C), (D) or (E):

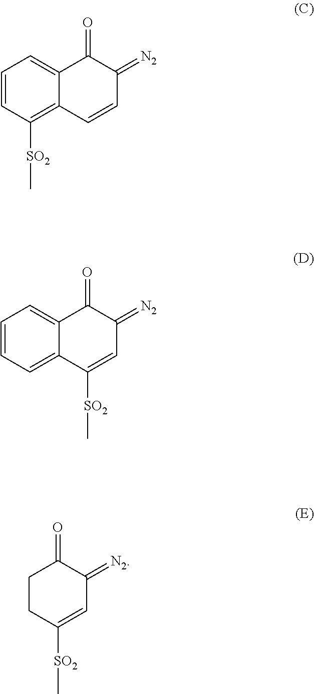

Generally, the structures of Formulae (C), (D) and/or (E) are incorporated into the photosensitive composition as an esterification product of the respective sulfonyl chloride (or other reactive moiety) and a phenolic compound, such as one of structures b-1 through b-6 shown below, each generally referred to as a photoactive compound or PAC, as discussed above. Thus, anyone, or any mixture of two or more of such PACs are combined with the polymer in forming a positive tone composition embodiment of the present invention. In each of Formulae (b-1) through (b-6), Q represents any of the structures of Formulae (C), (D) or (E). Advantageously, when a portion of a film or a layer of the photosensitive composition is exposed to appropriate actinic or electromagnetic radiation, these esterification products generate a carboxylic acid which enhances the solubility of such exposed portion in an aqueous alkali solution as compared to any unexposed portions of such film. Generally, such photosensitive materials are incorporated into the composition in an amount from 5 to 50 pphr polymer, where the specific ratio of the photosensitive material to polymer is a function of the dissolution rate of exposed portions as compared to unexposed portions and the amount of radiation required to achieve a desired dissolution rate differential. Advantageous photosensitive materials useful in embodiments in accordance with the present invention are shown in Formulae b-1 through b-6 below; additional useful photosensitive materials are exemplified in U.S. Pat. No. 7,524,594 B2 columns 14-20, pertinent portions of which are incorporated herein by reference:

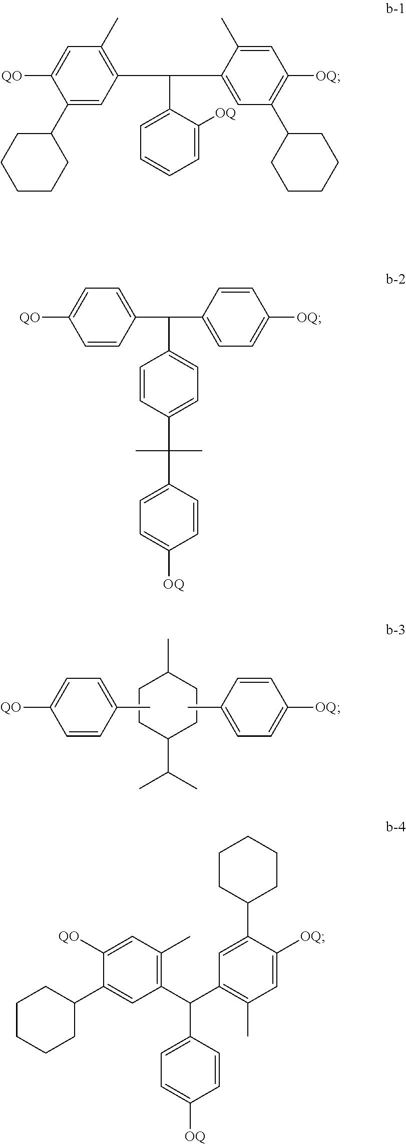

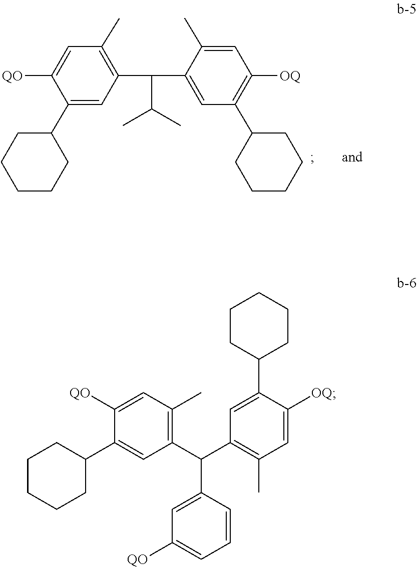

where at least one of Q is a group of the formula (C) or (D) and any remaining Q is hydrogen. An example of such photoactive compound available commercially include TrisP-3M6C-2(4)-201 from Toyo Gosei.

Any amount of photoactive compound can be employed in the photosensitive composition of this invention which brings about the desired results as described herein. Generally, such amount can range from 1 to 50 parts per hundred parts by mass (pphr) of the polymer (i.e., resin) as described herein. In some other embodiments such amount can range from 5 to 30 pphr.

Advantageously it has now been found that employing at least one suitable multifunctional crosslinking agent of formulae (IV) or (V) as describe herein in the photosensitive compositions of this invention provides a beneficial effect to the compositions of this invention. Such benefits include without any limitation improvement in mechanical and thermal properties, among others.

Any amount of crosslinking agent of formulae (IV) or (V) can be employed in the compositions of this invention that would bring about the intended benefit. In some embodiments the amount of one or more compounds of formulae (IV) or (V) that is employed in the composition of this invention may range from about 8 to 30 parts per hundred parts of the resin (pphr), i.e., the polymer used in such composition. In some other embodiments it ranges from about 10 to 25 pphr; in some other embodiments it ranges from about 12 to 20 pphr; and yet in some other embodiments it ranges from about 14 to 18 pphr. However, it should be noted that higher than 30 pphr of compounds of formulae (IV) or (V) may also be employed especially when more than one compound of formulae (IV) or (V) are employed.

Non-limiting examples of such multifunctional crosslinking agent of formulae (IV) or (V) that can be employed in the compositions of this invention include the following:

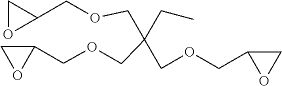 [SMILES: CCC(COCC1CO1)(COCC1CO1)COCC1CO1]

2,2′-(((2-ethyl-2-((oxiran-2-ylmethoxy)methyl)propane-1,3-diyl)bis(oxy))bis(methylene))bis(oxirane); also known as trimethylolpropane triglycidyl ether (from Nagase Chemtex, EX-321L);

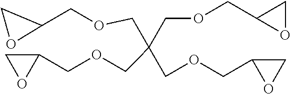 [SMILES: C(OCC(COCC1CO1)(COCC1CO1)COCC1CO1)C1CO1]

2,2′-(((2,2-bis((oxiran-2-ylmethoxy)methyl)propane-1,3-diyl)bis(oxy))bis(methylene))bis(oxirane); also known as pentaerythritol tetraglycidyl ether (PETG from Showa Denko);

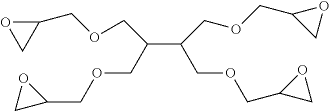 [SMILES: C(OCC(COCC1CO1)C(COCC1CO1)COCC1CO1)C1CO1]

2,2′-(((2-(1,3-bis(oxiran-2-ylmethoxy)propan-2-yl)propane-1,3-diyl)bis(oxy))bis(methylene))bis(oxirane);

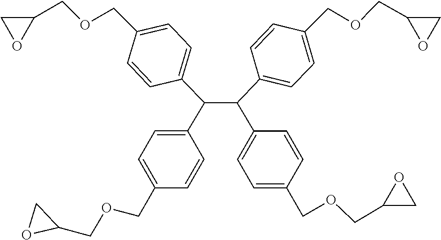 [SMILES: c1cc(C(c2ccc(COCC3CO3)cc2)C(c2ccc(COCC3CO3)cc2)c2ccc(COCC3CO3)cc2)ccc1COCC1CO1]

1,1,2,2-tetrakis(4-((oxiran-2-ylmethoxy)methyl)phenyl)ethane;

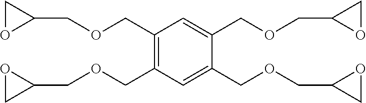 [SMILES: c1c(COCC2CO2)c(COCC2CO2)cc(COCC2CO2)c1COCC1CO1]

1,2,4,5-tetrakis((oxiran-2-ylmethoxy)methyl)benzene; and

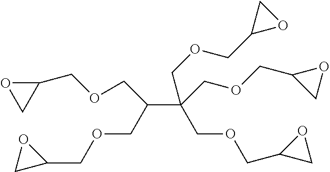 [SMILES: C(OCC(COCC1CO1)C(COCC1CO1)(COCC1CO1)COCC1CO1)C1CO1]

2,2′-(((2-(1,3-bis(oxiran-2-ylmethoxy)propan-2-yl)-2-((oxiran-2-ylmethoxy)methyl)propane-1,3-diyl)bis(oxy))bis(methylene))bis(oxirane).

Other suitable crosslinking agents including the following:

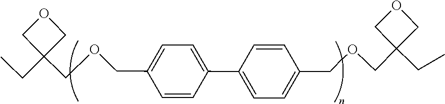

Where n=1 to 3 (OXBP), e.g., when n=1, 4,4′-bis(((3-ethyloxetan-3-yl)methoxy)methyl)-1,1′-biphenyl;

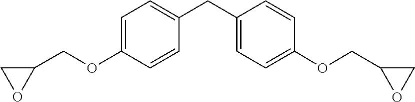 [SMILES: c1cc(OCC2CO2)ccc1Cc1ccc(OCC2CO2)cc1]

bis(4-(oxiran-2-ylmethoxy)phenyl)methane;

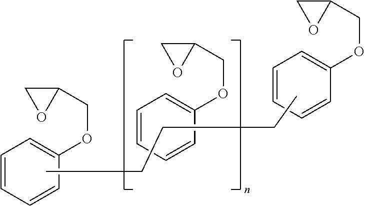

phenol-formaldehyde polymer glycidyl ether, where n=1 to 10 (EPON 862);

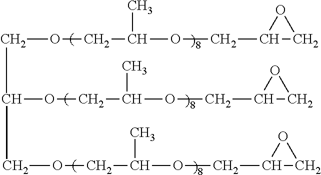

triglycidyl ether of poly(oxypropylene)epoxide ether of glycerol, commercially available as Heloxy 84 or GE-36 from Momentive Specialty Chemicals Inc.;

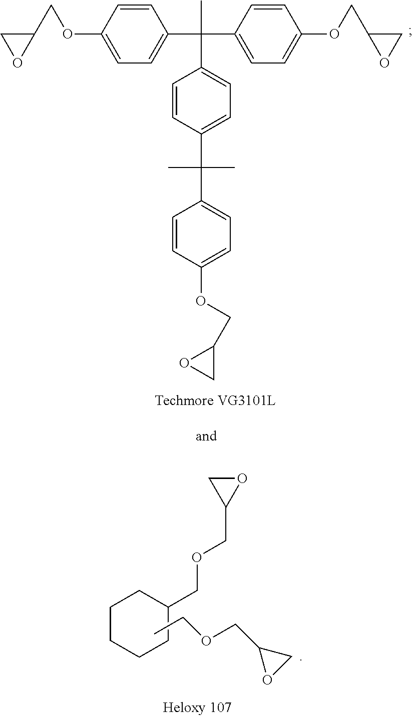

It has been further found that employing any one or more phenolic compounds of formula a-1 to a-6 further provides advantageous benefits to the composition of this invention. Several of these phenolic compounds are available commercially, such as for example, TrisP-3M6C-2 Ballast is available from Toyo Gosei. Again, any amount of one or more of the phenolic compound of formulae a-1 to a-6 can be employed in the photosensitive composition of this invention which brings about the desired results as described herein. Generally, such amount can range from 1 to 25 parts per hundred parts by mass (pphr) of the polymer (i.e., resin) as described herein. In some other embodiments such amount can range from 3 to 20 pphr and in some other embodiments such amount can range from 5 to 15 pphr.

As noted, one or more compounds of formula (VIA) and/or formula (VIB) are also employed in the compositions of this invention. Non-limiting examples of a compound of formula (VIA) or (VIB) may be enumerated as follows:
4-ethylresorcinol;
4-propylresorcinol;
4-butylresorcinol;
4-hexylresorcinol;
2-hydroxybenzoic acid;
3-hydroxybenzoic acid;
4-hydroxybenzoic acid;
4,4′-dihydroxydiphenyl sulfide;
3,3′-dihydroxydiphenyl disulfide;
4,4′-dihydroxydiphenyl disulfide;
4,4′-dihydroxydiphenyl sulfone;
2,2′-dihydroxydiphenyl ether;
4,4′-dihydroxydiphenyl ether;
biphenol;
2,2′-methylenediphenol (2,2′-dihydroxydiphenylmethane or o,o′-BPF);
4,4′-methylenediphenol;
2,2′-(ethane-1,1-diyl)diphenol;
4,4′-(ethane-1,1-diyl)diphenol;
2,2′-(propane-1,1-diyl)diphenol;
4,4′-(propane-1,1-diyl)diphenol;
2,2′-(propane-2,2-diyl)diphenol;
4,4′-(propane-2,2-diyl)diphenol;
4,4′-(1,3-dimethylbutylidene)diphenol;
2,2′-(4-methylpentane-2,2-diyl)diphenol;
4,4′-(4-methylpentane-2,2-diyl)diphenol;
4,4′-(2-ethylhexylidene)diphenol;
2,2′-(5-methylheptane-3,3-diyl)diphenol;
4,4′-(5-methylheptane-3,3-diyl)diphenol;
4,4′-ethylidenebisphenol;
2,2′-ethylenedioxydiphenol;
4,4′-(propane-2,2-diyl)bis(2-cyclohexylphenol);
4,4′-(2-methylpropane-1,1-diyl)bis(2-cyclohexyl-5-methylphenol);
5,5″-(cyclohexane-1,1-diyl)bis(([1,1′-biphenyl]-2-ol));
4,4′-(cyclohexane-1,1-diyl)bis(2-cyclohexylphenol);
4,4′-(4-methylcyclohexane-1,1-diyl)diphenol;
2-cyclohexyl-4-(2-(4-hydroxyphenyl)propan-2-yl)-5-methylphenol;
6,6′-methylenebis(2-(tert-butyl)-4-methylphenol);
6,6′-(2-methylpropane-1,1-diyl)bis(2,4-dimethylphenol);
4,4′-(2-methylpropane-1,1-diyl)bis(2-(tert-butyl)-5-methylphenol);
   and mixtures in any combination thereof.

Again, any amount of one or more compound of formulae (VIA) or (VIB) can be employed in the photosensitive composition of this invention which brings about the desired results as described herein. Generally, such amount can range from 5 to 30 parts per hundred parts by mass (pphr) of the polymer (i.e., resin) as described herein. In some other embodiments such amount can range from 7 to 20 pphr and in some other embodiments such amount can range from 9 to 15 pphr.

Advantageously, among other benefits, it has now been observed that by employing suitable amounts of one or more of the phenolic compounds as described herein surprisingly results in reduction of bubbles between the adhesive layer and the semiconductor chip in a semiconductor device using the photosensitive composition of this invention, especially, for example, when etching a wafer provided with a coating film or when crimping the semiconductor chips together through the adhesive layer. In addition, even when bubbles are generated between the adhesive layer and the semiconductor chip, the generated bubbles are removed due to the adhesive force of the adhesive layer to the semiconductor chip is enhanced, thus making it difficult for bubbles to be left at the interface between the adhesive layer and the semiconductor chip, and thus the semiconductor chips can be firmly bonded to each other. Therefore, a highly reliable chip laminate can finally be obtained.

Furthermore, since the photosensitive composition of the present invention contains a phenolic compound, an adhesive layer exhibiting relatively high solubility in organic solvents can be obtained in a semiconductor device using the photosensitive composition of the present invention. Therefore, even when it is necessary to remove a coating film obtained by, for example, applying the photosensitive composition to a wafer, the coating film can be efficiently dissolved and removed while suppressing formation of any residues. As a result, the wafer can be re-applied (reworked) to the bonding process without waste. Therefore, the process yield of the semiconductor device can be improved.

In some embodiments of this invention, the phenolic compound employed has two or more phenolic groups as described herein. But it has now been observed that a phenolic compound containing two to six phenolic functional group provides more beneficial effect. Further, in some embodiments, the composition of this invention contains two phenolic compounds; one having two phenolic groups and another phenolic compound having three or more phenolic groups. Thereby, the above-described effect can be more remarkably exerted.

The phenolic compounds contained in the composition of this invention may be a fused polycyclic structures as enumerated herein, such as for example, polycyclic phenolic compounds of formulae a-1 to a-6 or any such similar compounds known in the art as well as any of the phenolic compounds represented by formulae (VIA) or (VIB). Thus, in the semiconductor device using the photosensitive composition of the present invention, it is possible to obtain an adhesive layer having a particularly high adhesive force to the semiconductor chip and a better solubility in organic solvents.

The photosensitive compositions of the present invention also include additives that are advantageously capable of bonding with the pendant acidic group of the polymer resin. Such materials include, but are not limited to, additives that incorporate one or more epoxy groups such as a glycidyl group, an epoxycyclohexyl group, an oxetane group; an oxazoline group such as 2-oxazoline-2-yl group, a methylol group such as a N-hydroxy methylaminocarbonyl group or an alkoxymethyl group such as a N-methoxy methylaminocarbonyl group. Generally, the aforementioned bonding with the pendant acid group of the polymer is a cross-linking reaction that is initiated by heating to an appropriate temperature, generally above 110° C. for an appropriate amount of time. Accordingly, in some embodiments of this invention, the photosensitive composition of this invention, without any limitation, contains one or more epoxy compounds selected from the following:

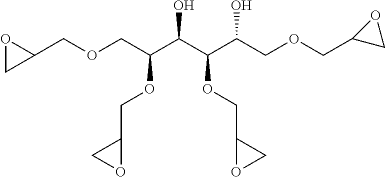 [SMILES: O[C@@H]([C@H](OCC1CO1)[C@H](O)COCC1CO1)[C@H](COCC1CO1)OCC1CO1]

(2R,3R,4R,5S)-1,3,5,6-tetrakis(oxiran-2-ylmethoxy)hexane-2,4-diol (also known as tetrakis-O-(oxiranylmethyl)-D-glucitol) (Denacol EX-614 from Nagase); and

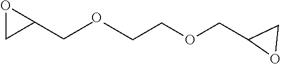

1,2-bis(oxiran-2-ylmethoxy)ethane.

Other exemplary cross-linking or crosslinkable materials that can be used as additives in the forming of a photosensitive composition of the present invention include, among others, bisphenol A epoxy resin, bisphenol F epoxy resin, silicone containing epoxy resins or the like, propylene glycol diglycidyl ether, polypropylene glycol diglycidyl ether, glycidyloxypropyltrimethoxysilane, polymethyl (glycidyloxypropyl)cyclohexane or the like; polymers containing oxazoline rings such as 2-methyl-2-oxazoline, 2-ethyl-2-oxazoline, 1,3-bis(2-oxazoline-2-yl)benzene, 1,4-bis(2-oxazoline-2-yl)benzene, 2,2′-bis(2-oxazoline), 2,6-bis(4-isopropyl-2-oxazoline-2-yl)pyridine, 2,6-bis(4-phenyl-2-oxazoline-2-yl)pyridine, 2,2′-isopropylidenebis (4-phenyl-2-oxazoline), (S,S)-(−)-2,2′-isopropylidenebis (4-tert-butyl-2-oxazoline), poly(2-propenyl-2-oxazoline) or the like; N-methylolacrylamide, N-methylol methacrylamide, furfuryl alcohol, benzyl alcohol, salicyl alcohol, 1,2-benzene dimethanol, 1,3-benzene dimethanol, 1,4-benzene dimethanol and resole type phenol resin or mixtures thereof. It has been found that, in general, such materials are effective at loadings from 5 pphr polymer to 40 pphr polymer. However, it should be understood that loadings higher or lower may also prove effective as their efficacy is dependent, at least in part, on the nature of the polymer employed and its mole percent of repeat units encompassing crosslinkable pendent groups.

In another aspect of this invention the photosensitive composition contains a compound or a mixture of compounds that are useful in enhancing the properties of the compositions, including but not limited to increasing the photo-speed and dissolution properties, among various other uses. Advantageously, it has now been found that a compound of formula (VII) can be used as an additive in accordance with the practice of this invention:

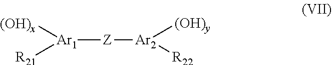

Where x and y are integers from 0 to 4. R₂₁ and R₂₂ are the same or different and independently of each other selected from hydrogen, halogen, methyl, ethyl, linear or branched C₃-C₁₈alkyl, C₁-C₁₈perfluoroalkyl, methoxy, ethoxy, linear or branched C₃-C₁₈alkoxy, C₃-C₁₆cycloalkyl, C₆-C₁₆bicycloalkyl, C₈-C₁₆tricycloalkyl, C₆-C₁₀aryl, C₇-C₁₈aralkyl, —(CH₂)_{w}CO₂R₂₃, —(CH₂)_{z}OR₂₄. Ar₁ and Ar₂ are the same or different and independently of each other selected from C₆-C₁₀aryl, C₇-C₁₈aralkyl, where the aryl or aralkyl groups can further be substituted with any of the possible substituents which are known to one skilled in the art. Z is selected from a bond, O, S, P, —NR—, —C(═O)—, —C(═O)—O—, —C(═O)—NR—, —SO—, —SO₂—, —SO₂NH— alkyl or any of the carbocyclic bridging group including, cycloalkyl, heterocycloalkyl, aryl, aralkyl, and the like. Where any of the cycloalkyl, bicycloalkyl or tricycloalkyl rings may contain one or more heteroatoms selected form O, S, N, P and Si. Where w is an integer from 0 to 8, R₂₃ is hydrogen, methyl, ethyl, linear or branched C₃-C₁₈alkyl. Where z is an integer from 0 to 8, R₂₄ is hydrogen, methyl, ethyl, linear or branched C₃-C₁₈alkyl. Where R is hydrogen, methyl, ethyl, linear or branched C₃-C₁₈alkyl, C₁-C₁₈perfluoroalkyl, C₃-C₁₆cycloalkyl, C₆-C₁₆bicycloalkyl, C₈-C₁₆tricycloalkyl.

In general, among other things, various compounds and additives as enumerated herein improve overall performance of the photosensitive compositions of this invention thus providing well defined photo-patterned structures having a variety of utilities, including but not limited to chip-stack applications, redistribution layers and for forming CMOS image sensor dam structures. Advantageously, it has also been found that certain of the additives as described herein may feature more than one function. For example, some of the additives as enumerated hereinabove may not only exhibit certain dissolution enhancement activity post-exposure but may also facilitate as a cross-linking agent as further described above. Therefore, additives as used herein do not limit the activity of such compounds to only one of such property but may also facilitate other functions of the photosensitive compositions of this invention.

It should further be noted that any of the additives noted above can be used alone, i.e., as a single compound and/or a combination of one or more compounds in any combination thereof. In addition, the amount of the additive that can be used depends upon the intended result with the photosensitive composition of this invention. Accordingly, any amount that would bring about the intended result can be used in this invention. In general, the amount of additive that can be used can range from 0.5 to 20 pphr, and in some embodiments such amounts are in the range of from 1 to 12 pphr.

The photosensitive composition of this invention further encompasses one or more compounds having utility as, among other things, adhesion promoters, antioxidants, crosslinking, coupling or curing agent, and the like. Representative examples of adhesion promoters or adhesion aids include vinyl silane such as vinyltrimethoxysilane or vinyltriethoxysilane; epoxysilanes such as 2-(3,4-epoxycyclohexyl)ethyltrimethoxysilane, 3-glycidoxypropylmethyldimethoxysilane, 3-glycidoxypropyltrimethoxysilane, 3-glycidoxypropyltriethoxysilane; styrylsilanes such as p-styryltrimethoxysilane; methacrylsilanes such as 3-methacryloxypropylmethyldimethoxysilane, 3-methacryloxypropyltrimethoxysilane, 3-methacryloxypropylmethyldiethoxysilane, 3-methacryloxypropyltriethoxysilane; acrylic silanes such as 3-acryloxypropyltrimethoxysilane; alkylsilane as further illustrated below; ureidosilane such as 3-ureidopropyltrialkoxysilane; mercaptosilane such as 3-mercaptopropylmethyldimethoxysilane, 3-mercaptopropyltrimethoxysilane; isocyanate silane such as 3-isocyanate propyltriethoxysilane; titanium-based compounds; aluminum chelates; representative examples include aluminum/zirconium-based compounds, among others. Non-limiting examples of other such compounds are selected from the group consisting of the following, commercially available materials are indicated by such commercial names.

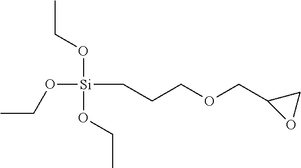 [SMILES: CCO[Si](CCCOCC1CO1)(OCC)OCC]

triethoxy(3-(oxiran-2-ylmethoxy)propyl)silane, also commonly known as 3-glycidoxypropyl triethoxysilane (3-GTS or (KBE-403 from Shin-Etsu Chemical Co., Ltd.));

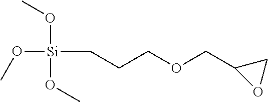

trimethoxy(3-(oxiran-2-ylmethoxy)propyl)silane, also commonly known as 3-glycidoxypropyl trimethoxysilane (KBM-403 from Shin-Etsu Chemical Co., Ltd.));
C₆H₅(CH₃O)₃Si phenyltrimethoxysilane C₆H₅(C₂H₅O)₃Si phenyltriethoxysilane (KBE-103 commercially available from Gelest or Shin-Etsu Chemical Co., Ltd.)

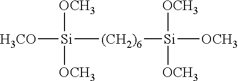

3,3,10,10-tetramethoxy-2,11-dioxa-3,10-disiladodecane (SIB-1832 from Gelest);

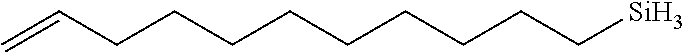

undec-10-en-1-ylsilane (SIU9048.0);

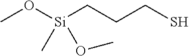

3-(dimethoxy(methyl)silyl)propane-1-thiol (SIM6474.0);

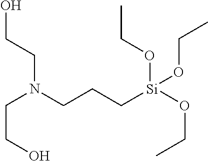 [SMILES: CCO[Si](CCCN(CCO)CCO)(OCC)OCC]

2,2′-((3-(triethoxysilyl)propyl)azanediyl)bis(ethan-1-ol) (SIB1140.0);

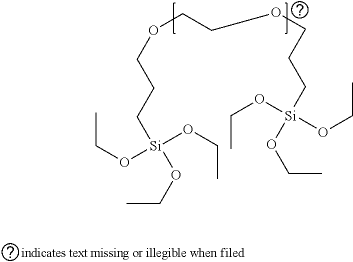

N,N′-bis[(3-triethoxysilylpropyl)aminocarbonyl]polyethylene oxide (SIB-1824.84 from Gelest);

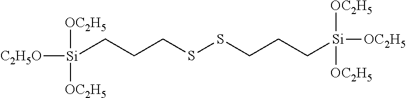

4,4,13,13-tetraethoxy-3,14-dioxa-8,9-dithia-4,13-disilahexadecane;

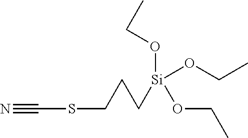 [SMILES: CCO[Si](CCCSC#N)(OCC)OCC]

triethoxy(3-thiocyanatopropyl)silane (SIT7908.0)

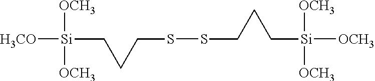 [SMILES: CO[Si](CCCSSCCC[Si](OC)(OC)OC)(OC)OC]

3,3,12,12-tetramethoxy-2,13-dioxa-7,8-dithia-3,12-disilatetradecane (Si-75 or Si-266 from Evonik);

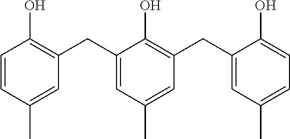 [SMILES: Cc1ccc(O)c(Cc2cc(C)cc(Cc3cc(C)ccc3O)c2O)c1]

2,2′-((2-hydroxy-5-methyl-1,3-phenylene)bis(methylene))bis(4-methylphenol) (antioxidant AO-80 from TCI Japan);

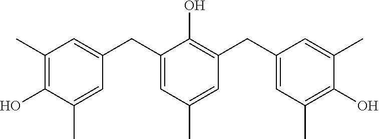 [SMILES: Cc1cc(Cc2cc(C)c(O)c(C)c2)c(O)c(Cc2cc(C)c(O)c(C)c2)c1]

4,4′-((2-hydroxy-5-methyl-1,3-phenylene)bis(methylene))bis(2,6-dimethylphenol) (Bis26X-PC)

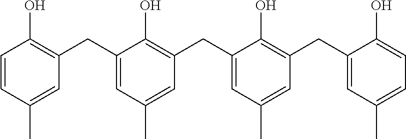 [SMILES: Cc1ccc(O)c(Cc2cc(C)cc(Cc3cc(C)cc(Cc4cc(C)ccc4O)c3O)c2O)c1]

6,6′-methylenebis(2-(2-hydroxy-5-methylbenzyl)-4-methylphenol) (4-PC);

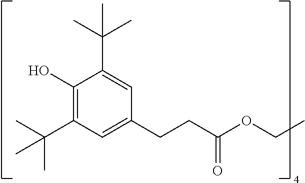

pentaerythritol tetrakis(3-(3,5-di-tert-butyl-4-hydroxyphenyl)propionate) (Irganox 1010 from BASF);

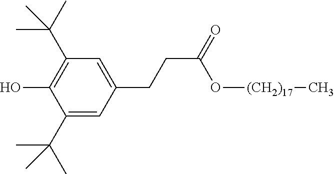

3,5-bis(1,1-dimethylethyl)-4-hydroxy-1-octadecyl ester Benzenepropanoic acid (Irganox 1076 from BASF):

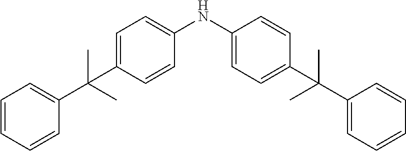 [SMILES: CC(C)(c1ccccc1)c1ccc(Nc2ccc(C(C)(C)c3ccccc3)cc2)cc1]

bis(4-(2-phenylpropan-2-yl)phenyl)amine (Naugard 445 (NG445) commercially available from Chemtura);

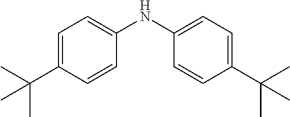 [SMILES: CC(C)(C)c1ccc(Nc2ccc(C(C)(C)C)cc2)cc1]

bis(4-(tert-butyl)phenyl)amine (Stearer Star from Seiko Chemical Products);

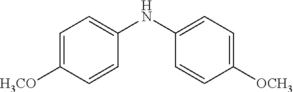 [SMILES: COc1ccc(Nc2ccc(OC)cc2)cc1]

bis(4-methoxyphenyl)amine (Thermoflex);

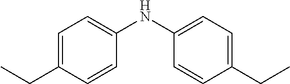 [SMILES: CCc1ccc(Nc2ccc(CC)cc2)cc1]

bis(4-ethylphenyl)amine;

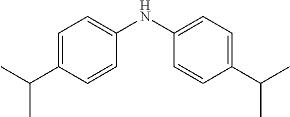 [SMILES: CC(C)c1ccc(Nc2ccc(C(C)C)cc2)cc1]

bis(4-isopropylphenyl)amine

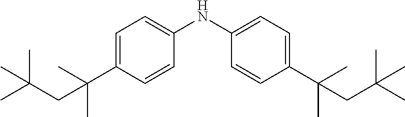 [SMILES: CC(C)(C)CC(C)(C)c1ccc(Nc2ccc(C(C)(C)CC(C)(C)C)cc2)cc1]

bis(4-(2,4,4-trimethylpentan-2-yl)phenyl)amine (Irganox 5057 from BASF);

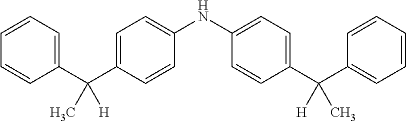 [SMILES: CC(c1ccccc1)c1ccc(Nc2ccc(C(C)c3ccccc3)cc2)cc1]

bis(4-(1-phenylethyl)phenyl)amine (Wingstay 29);

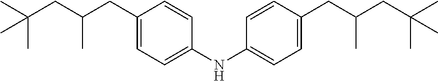 [SMILES: CC(Cc1ccc(Nc2ccc(CC(C)CC(C)(C)C)cc2)cc1)CC(C)(C)C]

bis(4-(2,4,4-trimethylpentyl)phenyl)amine (Irganox L 57 from BASF);

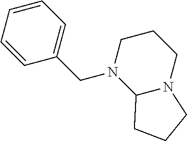 [SMILES: c1ccc(CN2CCCN3CCCC32)cc1]

1-benzyloctahydropyrrolo[1,2-a]pyrimidine (CGI-90 from BASF);

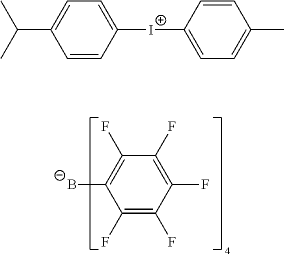

tetrakis(2,3,4,6-pentafluorophenyl)borate(1-)[4-(1-methylethyl)phenyl] (4-methylphenyl)-Iodonium (Rhodorsil PI 2074 from Blue Star Silicones)

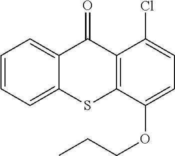 [SMILES: CCCOc1ccc(Cl)c2c(=O)c3ccccc3sc12]

1-chloro-4-propoxy-9H-Thioxanthen-9-one (CPTX from Lambson PLC);

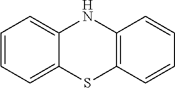 [SMILES: c1ccc2c(c1)Nc1ccccc1S2]

10H-phenothiazine (Phenothiazine from Kanto)

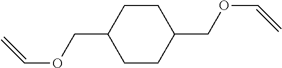

1,4-bis[(ethenyloxy)methyl]-cyclohexane (Cyclohexane Divinyl ether (CHDVE))

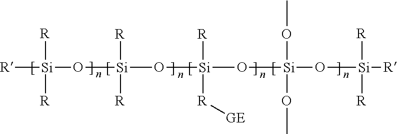

where R and R′ are independently (C₁-C₄)alkyl and GE=glycidyl ether (BY-16-115);

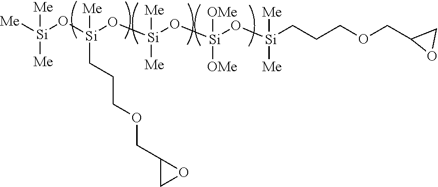

Silicone modified epoxy compound commercially available as BY16-115 from Toray-Dow Corning Silicone Co., Ltd.;

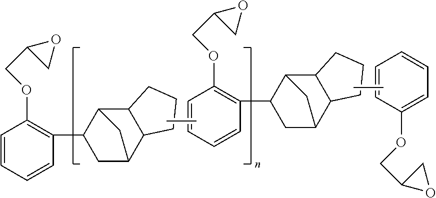

(HP-7200); and

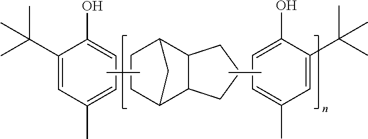

Lowinox CPL.

Still other exemplary epoxy resins or cross-linking additives include, among others Araldite MTO0163 and Araldite CY179 (manufactured by Ciba Geigy); and EHPE-3150, Epolite GT300 and (manufactured by Daicel Chemical).

It should again be noted that any one of these compounds can be used alone or as mixtures in any combination thereof, and only if needed depending upon the intended use and to obtain the desirable benefit. Again, any amount of one or more of aforementioned compounds can be used in the photosensitive composition of this invention so as to bring about the desired results. Generally, it has now been found that such amounts can range from 0.5 to 30 parts per hundred parts of the polymer resin (pphr). In some embodiments such amounts range from 1 to 10 pphr.

Photosensitive compositions in accordance with the present invention may also encompass other components as may be useful for the purpose of improving the properties of both the composition and the resulting film or the polymer layer. For example, the sensitivity of the composition to a desired wavelength of exposure radiation may result in improved desirable properties as further described below. Examples of such optional components may include without any limitation one or more compounds/various additives such as surfactants, silane coupling agents, leveling agents, phenolic resins, antioxidants, flame retardants, plasticizers, and curing accelerators.

The photosensitive composition embodiments, in accordance with the present invention, are generally dissolved in a solvent to form a homogeneous solution. Any of the solvents or a mixture thereof that would dissolve the co- or terpolymer and all of the additives as described herein can be employed. Non-limiting examples of such solvents include methyl ethyl ketone (MEK), propylene glycol monomethyl ether acetate (PGMEA), propylene glycol monomethyl ether (PGME), dimethylacetamide (DMAc), N-methylpyrrolidone (NMP), gamma-butyrolactone (GBL) and tetrahydrofuran (THF), and mixtures in any combination thereof. In some embodiments, the composition of this invention is dissolved in one or more solvents selected from the group consisting of propylene glycol monomethyl ether acetate (PGMEA) and propylene glycol monomethyl ether (PGME), and a mixture thereof.

Any amount of solvent that is needed to dissolve all of the ingredients of the photosensitive composition of the present invention can be used. Generally, such solvent can be not less than 50 parts by mass, not less than 100 parts by mass, or not less than 200 parts by mass. In some embodiments, the amount of solvent used is not less than 300 parts by mass, but may not be more than 400 parts by mass, or not more than 1000 parts by mass, or not more than 2000 parts by mass, or not more than 3000 parts by mass. In some embodiments the amount of solvent used is not more than 800 parts by mass, or not more than 1000 parts by mass, with respect to 100 parts by mass of polymer.

The photosensitive composition embodiments, in accordance with the present invention, are first applied to a desired substrate to form a film. Such a substrate includes any appropriate substrate as is, or may be used for electrical, electronic or optoelectronic devices, for example, a semiconductor substrate, a ceramic substrate, a glass substrate. With regard to said application, any appropriate coating method can be employed, for example spin coating, spraying, doctor blading, meniscus coating, ink jet coating and slot coating. For example, the photosensitive composition of this invention is applied to the entire surface of a silicon substrate having a dimension of 10×10 mm.

Next, the coated substrate is heated to facilitate the removal of residual casting solvent, for example to a temperature from 70° C. to 130° C. for from 1 to 40 minutes, although other appropriate temperatures and times can be used. After the heating, the film is generally imagewise exposed to an appropriate wavelength of actinic radiation, wavelength is generally selected based on the choice of the photoactive compound and/or photosensitizer incorporated into the polymer composition as described herein. However, generally such appropriate wavelength is from 200 to 700 nm. It will be understood that the phrase “imagewise exposure” means exposing through a masking element to provide for a resulting pattern of exposed and unexposed portion of the film.

After an imagewise exposure of the film formed from photosensitive composition or formulation embodiments in accordance with the present invention, a development process is employed. For the positive tone polymer formulations of the present invention, such development process removes only exposed portions of the film thus leaving a positive image of the masking layer in the film. For the negative tone polymer formulations of the present invention, such development process removes only unexposed portions of the film thus leaving a negative image of the masking layer in the film. For some embodiments, a post exposure bake can be employed prior to the aforementioned development process.

Suitable developers, particularly for positive tone formulations, such as the photosensitive compositions of this invention, can include aqueous solutions of inorganic alkalis such as sodium hydroxide, potassium hydroxide, sodium carbonate, ammonia, and aqueous solutions of organic alkalis such as 0.26N tetramethylammonium hydroxide (TMAH), ethylamine, triethylamine and triethanolamine. Accordingly, in some embodiments of this invention as described above, the photosensitive composition is soluble in an alkali developer.

Where an organic alkali is used, generally an organic solvent essentially fully miscible with water is used to provide adequate solubility for the organic alkali. Aqueous solutions of TMAH are well known developer solutions in the semiconductor industry. Suitable developers can also include organic solvents such as propylene glycol methyl ether acetate (PGMEA), 2-heptanone, cyclohexanone, toluene, xylene, ethyl benzene, mesitylene and butyl acetate, among others.

Thus, some formulation embodiments of the present invention provide self-imageable films that after imagewise exposure, the resulting image is developed using an aqueous base solution, while for other such embodiments the resulting image is developed using an organic solvent. Regardless of which type of developer is employed, after the image is developed, the substrate is rinsed to remove excess developer solution, typical rinse agents are water or appropriate alcohols and mixtures thereof.

After the aforementioned rinsing, the substrate is dried and the imaged film finally cured. That is to say, the image is fixed. Where the remaining layer has not been exposed during the imagewise exposure, image fixing is generally accomplished by causing a reaction within the remaining portions of the film. Such reaction is generally a cross-linking reaction that can be initiated by heating and/or non-imagewise or blanket exposure of the remaining material. Such exposure and heating can be in separate steps or combined as is found appropriate for the specific use of the imaged film. The blanket exposure is generally performed using the same energy source as employed in the imagewise exposure although any appropriate energy source can be employed. The heating is generally carried out at a desirable temperature, for example, from above 110° C. for a time of from 40 min to one or more hours. Where the remaining layer has been exposed during the imagewise exposure, image fixing is generally accomplished by a heating step to be tailored to complete any reaction initiated by the exposure. However, an additional blanket exposure and heating, as discussed above, can also be employed. It should be realized, however, that the choice of a final cure process is also a function of the type of device being formed; thus, a final fixing of the image may not be a final cure where the remaining layer is to be used as an adhesive layer or structure.

The devices are produced by using embodiments of the alkali soluble photosensitive resin composition of the present invention to form layers which are characterized as having high heat resistance, an appropriate water absorption rate, high transparency, and low permittivity. In addition, such layers generally have an advantageous coefficient of elasticity after curing, 0.1 kg/mm² to 200 kg/mm² being typical.

As previously mentioned, exemplary applications for embodiments of the photosensitive compositions in accordance with the present invention include die attach adhesive, wafer bonding adhesive, insulation films (interlayer dielectric layers), protecting films (passivation layers), mechanical buffer films (stress buffer layers) or flattening films for a variety of semiconductor devices, and printed wiring boards. Specific applications of such embodiments encompass a die-attach adhesive to form a single or multilayer semiconductor device, dielectric film which is formed on a semiconductor device; a buffer coat film which is formed on the passivation film; an interlayer insulation film which is formed over a circuit formed on a semiconductor device.

Accordingly, some embodiments in accordance with the present invention therefore provide a positive tone photosensitive polymer composition which exhibits enhanced characteristics with respect to one or more of mechanical properties (such as low-stress retained elongation to break after aging) and at least equivalent chemical resistance, as compared to alternate materials. In addition, such embodiments provide generally excellent electrical insulation, adhesion to the substrate, and the like. Thus, semiconductor devices, device packages, and display devices are provided that incorporate embodiments in accordance with the present invention.

Advantageously, it has now been found that the photosensitive compositions of this invention are useful to form adhesive layers for bonding the semiconductor chips to each other, such as in chip-stack applications. For example, a bonding layer used for such a purpose is composed of a cured product of the photosensitive adhesive composition of the present invention. Surprisingly, it has now been found that although the adhesive layer is a single-layer structure, it not only exhibits sufficient adhesiveness to the substrate but also is free of significant stress resulting due to the curing step. Accordingly, it is now possible to avoid undesirably thick layer of film encompassing the chip as a laminate. It has been further observed that the laminates formed in accordance with the present invention are reliable in that the relaxation of stress concentration between layers caused by thermal expansion difference or the like can be obtained. As a result, the semiconductor device having low height and high reliability can be obtained. That is, devices with low aspect ratio and low thickness can be obtained. Such semiconductor device becomes particularly advantageous to electronic equipment, which has very small internal volume and is in use while carrying as a mobile device, for example. Even more advantageously, by practice of this invention it is now possible to form a variety of electronic devices featuring hitherto unachievable level of miniaturization, thinning and light-weight, and the function of the semiconductor device is not easily damaged even if such devices are subject to rugged operations such as swinging or dropping.

A cured product of the photosensitive adhesive composition of the present invention, i.e., the adhesive layer or the film generally exhibits an excellent adhesiveness to a suitable substrate, such as for example a semiconductor chip, and adhesiveness strength can be measured by any of the known methods such as for example die shear strength. Accordingly, in some embodiments the photosensitive composition of this invention exhibits die shear strength higher than 3.0 MPa, higher than 4.0 MPa, higher than 5.0 MPa, higher than 6.0 MPa, higher than 6.5 MPa, higher than 7.0 MPa, higher than 8.0 MPa, higher than 9.0 MPa, higher than 10.0 MPa, and so on. In some embodiments the photosensitive composition of this invention exhibits die shear strength in the range of from about 5.0 MPa to 10.0 MPa. However, it should be noted that the upper limit of the die-share strength of the photosensitive resin composition is not particularly limited, but may be, for example, 30.0 MPa or less, 20.0 MPa or less, 15.0 MPa or less, and 12.0 MPa or less.

The die shear strength can be measured by any of the known procedures in the art. For example, a photosensitive resin composition is applied to the entire surface of a silicon substrate having a dimension of 10×10 mm, and heat treated at 120° C. for 30 to 60 minutes to produce a cured product having a thickness of 1 μm. After placing a suitable test substrate such as for example a silicon substrate having a dimension of 5×5 mm on the surface of the cured product, a heat press is performed at 150° C. at a force of about 25 N for 10 seconds from the top of the silicon substrate in the direction of the cured product using a heat press machine, and the silicon substrate and the cured product are crimped to obtain a specimen. The specimen is then heat treated under a nitrogen atmosphere at 230° C. for 60 minutes. The die shear strength between the silicon substrate and the hardened material in the specimen is then measured at 180° C. at a tester distance of 5 μm from the surface of the hardened material and a tester speed of 300 μm/second.

Further, in some embodiments of this invention as described above, the electronic and/or the semiconductor device according to this invention encompass a laminated semiconductor element where said lamination consists of a photosensitive composition according to the present invention.

In some embodiments of this invention, the semiconductor device encompassing a redistribution layer (RDL) structure further incorporates a photosensitive composition according to this invention.

Further, in some embodiments of this invention as described above, the semiconductor device encompassing a chip stack structure further includes a photosensitive composition according to this invention.

In yet some other embodiments of this invention as described above, the semiconductor device encompassing a complementary metal oxide semiconductor (CMOS) image sensor dam structure further incorporates a photosensitive composition according to this invention. In yet some other embodiments of this invention, the semiconductor device encompassing a photosensitive composition of this invention includes, for example, various semiconductor packages in which transistors, diodes, solid-state imaging devices, semiconductor chips and the like are laminated and sealed; Wafer-Level Chip-Size Package (WLP); display devices such as LCD displays, OLED displays, touch panels, electronic paper, color filters, mini-LED displays, and micro-LED displays; light receiving devices such as solar cells can be envisioned.

In addition, in some embodiments of this invention as described above, a film is formed by the photosensitive composition according to this invention. As further described above, such films generally exhibit excellent chemical, mechanical, elastic properties having a wide variety of utility in electronic, optoelectronic, microelectromechanical applications featuring excellent dielectric properties.

Accordingly, in some embodiments of this invention, there is provided a microelectronic or optoelectronic device encompassing one or more of a redistribution layer (RDL) structure, a chip-stack structure, a CMOS image sensor dam structure, where said structures further incorporates a photosensitive composition according to this invention.

Further, in some embodiments of this invention, there is provided a method of forming a film for the fabrication of a microelectronic or optoelectronic device comprising:
coating a suitable substrate with a composition according to the invention to form a film;
patterning the film with a mask by exposing to a suitable radiation;
developing the film after exposure to form a photo-pattern; and
curing the film by heating to a suitable temperature.

The coating of the substrate with photosensitive composition of this invention can be performed by any of the coating procedures as described herein and/or known to one skilled in the art, such as by spin coating.

In addition, the developing in accordance with the method of this invention can be performed by any of the known developing techniques such as by the use of an aqueous developer.

In some embodiments of this invention, the method according to this invention utilizes a developer, which is aqueous tetramethylammonium hydroxide (TMAH).

In addition, in some of the embodiments of this invention, a substrate is first hardbaked in the method according to this invention before the curing step at a temperature of from 130° C. to 160° C. for 20 minutes to 60 minutes.

Finally, in some other embodiments of this invention, the curing is performed at a temperature of from 170° C. to 200° C. at an incremental heating ramp of 5° C. and for 1 to 5 hours.

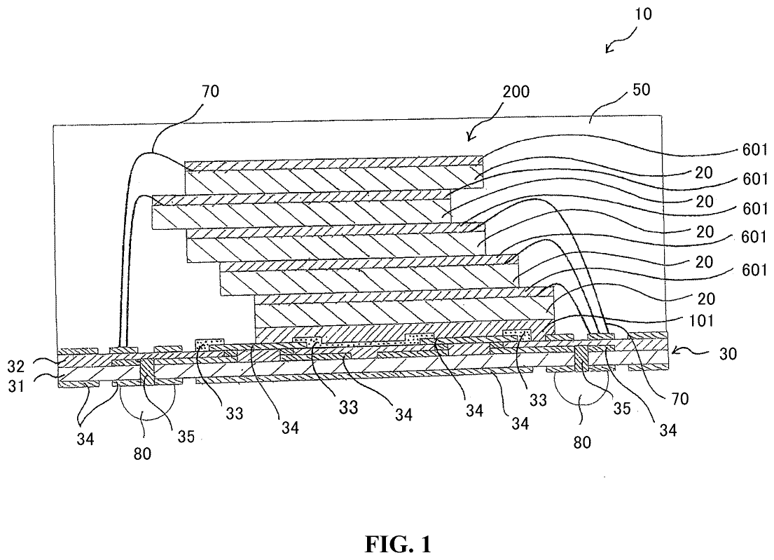

Now turning specifically to FIG. 1, a sectional view of an embodiment of a semiconductor device of the present invention is shown.

In an embodiment of this invention there is further provided a semiconductor device which is comprised of a stacked semiconductor element, wherein the stacked semiconductor element includes a plurality of semiconductor elements and a hardened object of the present composition embodiment between the semiconductor elements. Since the photosensitive composition of the present invention has improved adhesiveness, the semiconductor elements are well adhered to each other. The semiconductor device of the present invention is described with reference to FIG. 1, which is a schematic cross-sectional view schematically showing an example of the structure of the semiconductor device of the present invention. The semiconductor device 10 shown in FIG. 1 is an example having a semiconductor package in ball grid array (BGA). The semiconductor device 10 encompasses a plurality of semiconductor chips (semiconductor elements) 20 laminated with each other, an adhesive layer 601 adhering the semiconductor chips 20 with each other, a package substrate 30 supporting the semiconductor chip 20, an adhesive layer 101 adhering the semiconductor chip 20 with the package substrate 30, a mold portion 50 sealing the semiconductor chip 20, and a solder ball 80 provided on a lower side of the package substrate 30. Each member is sequentially described in detail below.

Any kind of elements may be employed for the semiconductor chip 20, and examples thereof include a memory element such as NAND (not AND) flash memory and DRAM, and an integrated circuit element such as IC (Integrated Circuit) and LSI (Large Scale Integration).

Constituent materials of the semiconductor chip 20 are, for example, single crystal material, polycrystalline material or amorphous material of silicon, silicon carbide or the like, but not particularly limited thereto.

A plurality of semiconductor chips 20 are laminated in such a way as to shift slightly from each other in its plane direction, thereby a chips-laminated body 200 (stacked semiconductor element) is configured. Interspaces between the semiconductor chips 20 are adhered via the adhesive layer 601. The adhesive layer 601 is also provided on the upper surface of the chips-laminated body 200, which is also composed of a cured product of the photosensitive composition embodiment of this invention (the cured photosensitive composition).

The package substrate 30 shown in FIG. 1 is a build-up substrate comprising a core substrate 31, an insulating layer 32, a solder resist layer 33, a wiring 34, and a conductive via 35.

Among them, the core substrate 31 is a substrate supporting the semiconductor device 10, and is made of, for example, a composite material or a glass cloth filled with a resin material.

The insulating layer 32 is an interlayer insulating layer to insulate between the wires 34 and between the wiring 34 and the conductive via 35, and is formed of, for example, a resin material. The solder resist layer 33 is a surface protective layer for protecting the wiring formed on the outermost surface of the package substrate 30, and is formed of, for example, a resin material.

The wire 34 and the conductive via 35 are transmission paths of electric signals, respectively, and are made of, for example, a metal material such as a simple substance or an alloy of Au, Ag, Cu, Al or Ni.

The solder ball 80 is electrically connected to the wiring 34, and functions as an electrode connecting the wiring 34 with another electrical circuit by being fused to an external electrical circuit.

The chips-laminated body 200 formed by laminating the plurality of semiconductor chips 20 is placed on the upper surface of the package substrate 30. The interspace between the chips-laminated body 200 and the package substrate 30 is adhered by the adhesive layer 101.

A part of the wiring 34 of the package substrate 30 is exposed on the upper surface of the package substrate 30, and this exposed portion and an electrode portion of each semiconductor chip 20 are connected by a bonding wire 70.

The mold portion 50 shown in FIG. 1 covers the side surface and the top surface of the chip-laminate layer 200, and is formed so as to cover the entire upper surface of the package substrate 30. Thus, it is possible to protect the chips-laminated body 200 from the external environment. For example, such mold portion 50 is made of, for example, any of the resin material, such as epoxy resin or phenol resin.

The semiconductor device according to the present embodiment may be a semiconductor device comprising a semiconductor element, a member to be bonded, and a cured material according to the present embodiment between the semiconductor element and the member to be bonded. Since the photosensitive composition according to the present embodiment has improved adhesiveness, the semiconductor element and the member to be bonded are well bonded.

Although the present invention has been described above, the present invention is not limited thereto. For example, any component may be added to the photosensitive resin composition. In addition, any structure may be added to the semiconductor device.

### EXAMPLES

The following abbreviations have been used hereinbefore and hereafter in describing some of the compounds, instruments and/or methods employed to illustrate certain of the embodiments of this invention:
EPEsNB—ethyl 3-(bicyclo[2.2.1]hept-2-en-2-yl)propanoate; NBTON—trioxanonanenorbornene; PhOAcNB—4-(bicyclo[2.2.1]hept-5-en-2-yl)phenyl acetate; PhOHNB—4-(bicyclo[2.2.1]hept-5-en-2-yl)phenol; EugOAcNB—4-norbornenylmethyl-2-methoxyphenol acetate; EugOHNB—4-(bicyclo[2.2.1]hept-4-en-2-ylmethyl)-2-methoxyphenol; HexNB—4-(bicyclo[2.2.1]hept-5-ene-2-yl)hexane; MeOAcNB—bicyclo[2.2.1]hept-5-en-2-ylmethyl acetate; HFANB—norbornenyl-2-trifluoromethyl-3,3,3-trifluoropropan-2-ol; PGMEA—propylene glycol monomethyl ether acetate; PGME—propylene glycol monomethyl ether; PAC—TrisP-3M6C-2(4)-201 as described herein having the structure b-1; epoxy compound 1—trimethylolpropane triglycidyl ether; epoxy compound 2—pentaerythritol tetraglycidyl ether; phenolic compound 1—(4, 4′-[(2-hydroxyphenyl) methylene]bis [2-cyclohexyl-5 methylphenol]), also represented herein as formula a-1 (TrisP-3M6C-2, available from Honshu Chemical Co., Ltd.); phenolic compound 2—2,2′-dihydroxydiphenylmethane (o, o′-BPF, available from Honshu Chemical Co., Ltd.); KBE-103—phenyltriethoxysilane; TMAH—tetramethylammonium hydroxide.

The polymers as described hereinabove and hereafter which are used in the compositions of this invention can be prepared using generally known literature procedures for preparing such similar vinyl addition polymers. See for example, U.S. Pat. Nos. 8,753,790 B2 and 9,696,623 B2, pertinent portions from both of which are incorporated herein by reference.

### Examples 1 to 15

In general, any of the copolymers or terpolymers as described herein can be used. For example, either a copolymer or a terpolymer of polynorbornene derivatives as listed in Table 1 was dissolved in a suitable solvent such as PGMEA or PGME. To this polymer solution was then added specific amounts of additives, expressed as parts per hundred resin (pphr), as summarized in Table 2 in an appropriately sized amber HDPE bottle. The mixture was rolled for 18 hours to produce a homogeneous solution. Particle contamination was removed by filtering the polymer solution through a 0.45 μm pore polytetrafluoroethylene (PTFE) disc filter under 35 psi pressure, the filtered polymer solution was collected in a low particle HDPE amber bottle and the resulting solution stored at 5° C.

TABLE 1

| | | | | | M_{w} of |
|---|---|---|---|---|---|
| | EPEsNB | NBTON | PhOAcNB | EugOAcNB | Polymer |
| Example 1 | 30 | 62 | 0 | 8 | 62279 |
| Example 2 | 30 | 62 | 0 | 8 | 62279 |
| Example 3 | 30 | 62 | 0 | 8 | 62279 |
| Example 4 | 30 | 62 | 0 | 8 | 62279 |
| Example 5 | 30 | 62 | 0 | 8 | 62279 |
| Example 6 | 30 | 62 | 0 | 8 | 62279 |
| Example 7 | 30 | 62 | 0 | 8 | 62279 |
| Example 8 | 30 | 62 | 0 | 8 | 62279 |
| Example 9 | 30 | 65 | 0 | 5 | 62408 |
| Example 10 | 30 | 62 | 8 | 0 | 62560 |
| Example 11 | 30 | 62 | 8 | 0 | 62560 |
| Example 12 | 30 | 62 | 8 | 0 | 62560 |
| Example 13 | 30 | 70 | 0 | 0 | 62206 |
| Example 14 | 25 | 75 | 0 | 0 | 72173 |
| Example 15 | 35 | 65 | 0 | 0 | 75700 |

M_{w}—weight average molecular weight

TABLE 2

| Ingredients | | | | | | | | | | | | | | | |
|---|---|---|---|---|---|---|---|---|---|---|---|---|---|---|---|
| (pphr by mass) | Ex. 1 | Ex. 2 | Ex. 3 | Ex. 4 | Ex. 5 | Ex. 6 | Ex. 7 | Ex. 8 | Ex. 9 | Ex. 10 | Ex. 11 | Ex. 12 | Ex. 13 | Ex. 14 | Ex. 15 |
| Polymer | 100 | 100 | 100 | 100 | 100 | 100 | 100 | 100 | 100 | 100 | 100 | 100 | 100 | 100 | 100 |
| PAC | 15 | 15 | 15 | 15 | 20 | 20 | 75 | 90 | 15 | 30 | 15 | 30 | 30 | 30 | 30 |
| Epoxy compound 1 | 15 | 0 | 15 | 15 | 15 | 20 | 15 | 15 | 15 | 15 | 15 | 0 | 30 | 30 | 30 |
| Epoxy compound 2 | 5 | 10 | 5 | 5 | 5 | 0 | 5 | 5 | 5 | 5 | 0 | 45 | 15 | 15 | 15 |
| Phenolic Compound 1 | 5 | 5 | 0 | 15 | 5 | 5 | 5 | 5 | 5 | 5 | 5 | 5 | 5 | 5 | 5 |
| Phenolic Compound 2 | 10 | 10 | 0 | 20 | 10 | 10 | 10 | 10 | 10 | 10 | 10 | 10 | 10 | 10 | 10 |
| KBE-103 | 10 | 10 | 10 | 10 | 10 | 10 | 10 | 10 | 10 | 10 | 10 | 10 | 10 | 10 | 10 |
| PGMEA | 500 | 500 | 500 | 500 | 500 | 500 | 500 | 500 | 500 | — | — | — | 500 | 500 | 500 |
| PGME | — | — | — | — | — | — | — | — | — | 500 | 500 | 500 | — | — | — |
| Glass Trans. | 345 | — | — | — | 350 | — | — | 355 | 342 | — | 335 | — | 350 | — | — |
| Temp. (° C.) | | | | | | | | | | | | | | | |
| Elongation | 29 | — | — | — | 25 | — | — | 23 | 25 | — | 25 | — | 27 | — | — |
| at Break (%) | | | | | | | | | | | | | | | |
| Tensile | 40 | — | — | — | 46 | — | — | 58 | 36 | — | 42 | — | 42 | — | — |
| Strength (MPA) | | | | | | | | | | | | | | | |
| Patternability | A | A | A | A | A | A | A | A | A | A | A | A | A | A | A |
| Die Shear | 10 | 8 | 10 | 10 | 8 | 5 | 4 | 4 | 9 | 9 | 10 | 8 | 8 | 6 | 7 |
| Strength (MPa) | | | | | | | | | | | | | | | |

A: An opening with a width of 100 μm was formed

The compositions thus formed were brought to room temperature and was applied to several 125 mm diameter silicon wafers (thickness: 625 μm) by spin coating initially at 200 rpm for 10 seconds and then at 500 rpm for 30 seconds. The substrates so formed were then placed on a 120° C. hot plate for 5 minutes, providing about a 1 micron (μm) thick polymer film. Each of the polymer film was then imagewise exposed through a line and space pattern mask having a width of 100 m. The exposure was carried out by irradiating light having a wavelength of 365 nm and a light intensity of 5 mW/cm². Each film was then developed using a puddle development method at 23° C. having about 40 seconds immersions in TMAH aqueous solution (2.38% solution). After the develop process, each wafer was rinsed by spraying deionized water for 20 seconds and then dried by spinning at 3000 rpm for 15 seconds.

The developed coating film (adhesive layer) was then observed with an optical microscope, and patternability was evaluated based on the following evaluation criteria. The results are shown in Table 2. In each of Examples 1 to 7, an opening with a width of 100 μm was formed.

### Example 2

### Die Shear Strength Measurements

Each of the compositions as described in Examples 1 to 15 was spin-coated onto a 10 mm×10 mm silicon wafer and heat treated at 120° C. for 40 minutes to form a cured film having a thickness of about 1 μm. The film was hardbaked at 150° C. for 40 min. Then, the wafer was singulated into 5 mm×5 mm chips. Next, the chips were placed on a 150° C. hotplate while a separate 5 mm×5 mm silicon chip was pressed into the surface of the coated singulated chip for 10 seconds with a force of 25 N from the top of the Si test piece in the direction of the cured product using a heat press machine, and the test piece and the cured product were crimped to obtain a specimen. The test piece was then heat treated at 230° C. for 60 minutes under a nitrogen atmosphere. The die shear strength between the Si test piece and the hardened piece in the test piece was then measured at 180° C. at a tester distance of 5 m from the surface of the hardened piece and a tester speed of 300 m/sec. The results are summarized in Table 2.

It is clear from the data presented in Tables 1 and 2 the photosensitive compositions of the present invention as specifically exemplified in Examples 1 to 15 exhibit excellent photopatterning properties as demonstrated by an opening of 100 μm in width in all of the patternability evaluation as summarized in Table 2. In addition, the die shear strength was 4 MPa or more and can be readily tailored to exhibit higher die shear strength up to 10 MPa as seen in many of the Examples summarized in Table 2. Most advantageously, the content of fluorine in all of the compositions of Examples 1 to 15 was 0.0 mass %, thus providing hitherto unavailable environmental benefits.

Therefore, it is understood that the performance balance of patternability, adhesiveness and environmental compatibility was improved in the photosensitive resin composition of Example 1˜15.

Although the invention has been illustrated by certain of the preceding examples, it is not to be construed as being limited thereby; but rather, the invention encompasses the generic area as hereinbefore disclosed. Various modifications and embodiments can be made without departing from the spirit and scope thereof.

What is claimed is:

1. A photosensitive composition comprising:
a) a polymer having a first repeating unit of formula (IA) derived from a monomer of formula (I): 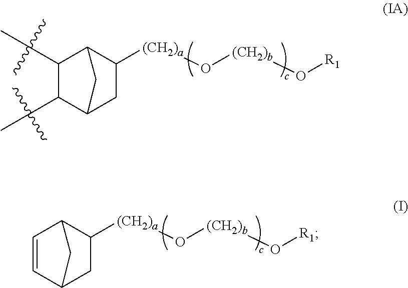
and
a second repeating unit of formula (IIA) derived from a monomer of formula (II): 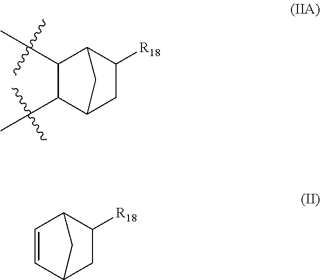
wherein: [symbol]
represents a position at which the bonding takes place with another repeat unit;
a is an integer from 0 to 3;
b is an integer from 1 to 4;
c is an integer from 1 to 4;
R₁ is selected from the group consisting of hydrogen, methyl, ethyl, n-propyl, i-propyl and n-butyl;
R₁₈ is —(CH₂)ᵥ—CO₂R₁₉ where v is an integer from 0 to 4, and
R₁₉ is hydrogen or (C₁-C₄)alkyl;
b) a photo active compound containing a diazo-quinone moiety of formula (A): 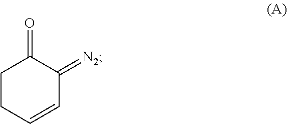
c) a multifunctional crosslinking agent selected from the group consisting of:
a compound of formula (IV): 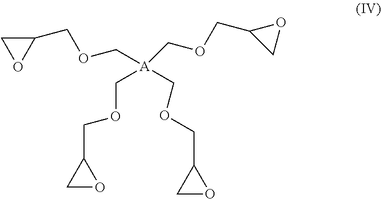
and
a compound of formula (V): 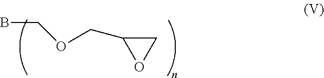
wherein:
n is an integer from 3 to 8;
A is selected from the group consisting of C, CH—(CR₂)_{d}—CH and substituted or unsubstituted aryl, where d is an integer from 0 to 4 and R is selected from the group consisting of hydrogen, methyl, ethyl, n-propyl, i-propyl and n-butyl;
B is selected from the group consisting of substituted or unsubstituted (C₁-C₆)alkyl, (C₂-C₆)alkylene and substituted or unsubstituted aryl;
wherein said substituents are selected from the group consisting of halogen, methyl, ethyl, linear or branched (C₃-C₆)alkyl, (C₃-C₈)cycloalkyl, (C₆-C₁₀)aryl, (C₇-C₁₂)aralkyl, methoxy, ethoxy, linear or branched (C₃-C₆)alkyloxy, (C₃-C₈)cycloalkyloxy, (C₆-C₁₀)aryloxy and (C₇-C₁₂)aralkyloxy;
d) a phenolic compound selected from the group consisting of:

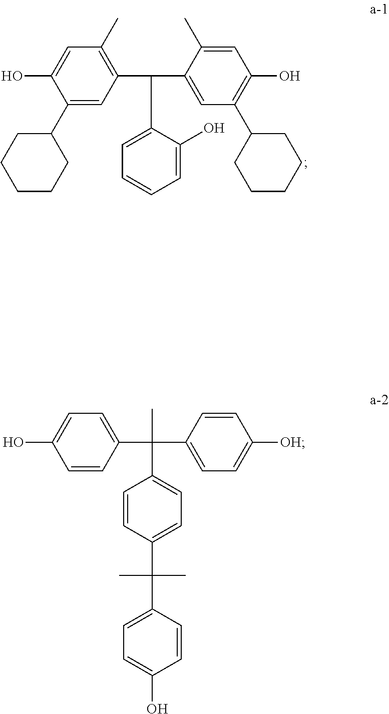 [SMILES: Cc1cc(O)c(C2CCCCC2)cc1C(c1cc(C2CCCCC2)c(O)cc1C)c1ccccc1O ; CC(C)(c1ccc(O)cc1)c1ccc(C(C)(c2ccc(O)cc2)c2ccc(O)cc2)cc1]

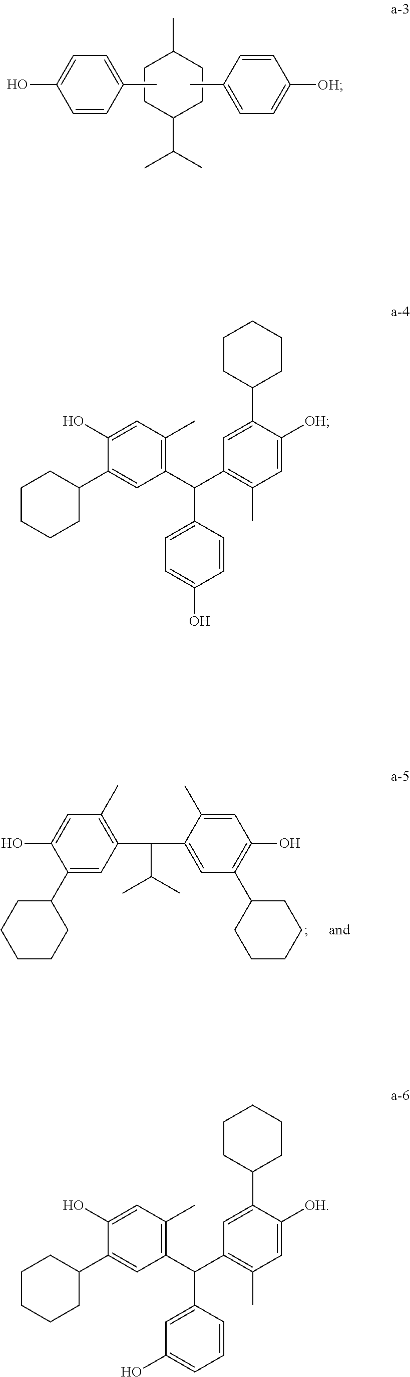

2. The photosensitive composition of claim 1 wherein the first repeat unit of the polymer is derived from a monomer selected from the group consisting of:
trioxanonanenorbornene (NBTON);
tetraoxadodecanenorbornene (NBTODD);
5-(3-methoxybutoxy)methyl-2-norbornene (NB-3-MBM); and
5-(3-methoxypropanoxy)methyl-2-norbornene (NB-3-MPM).

3. The photosensitive composition of claim 1 wherein the second repeat unit of the polymer is derived from a monomer selected from the group consisting of:
3-(bicyclo[2.2.1]hept-5-en-2-yl)acetic acid (NBMeCOOH);
ethyl 3-(bicyclo[2.2.1]hept-2-en-2-yl)propanoate (EPEsNB);
bicyclo[2.2.1]hept-5-ene-2-carboxylic acid (Acid NB) and norbornenylpropanoic acid (NBEtCOOH).

4. The photosensitive composition of claim 1 wherein the polymer is further comprising of a third repeating unit of formula (IIIA) derived from a monomer of formula (III): 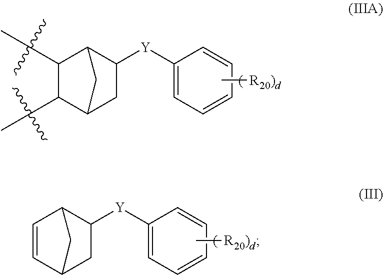
wherein,
d is an integer from 1 to 4;
Y is a bond or CH₂;
each R₂₀ is independently selected from the group consisting of hydroxy, methoxy and acetoxy.

5. The photosensitive composition of claim 4 wherein the third repeat unit of the polymer is derived from a monomer selected from the group consisting of:
4-(bicyclo[2.2.1]hept-5-en-2-yl)phenyl acetate (PhOAcNB);
4-(bicyclo[2.2.1]hept-5-en-2-yl)phenol (PhOHNB);
4-norbornenylmethyl-2-methoxyphenol acetate (EugOAcNB); and
4-(bicyclo[2.2.1]hept-4-en-2-ylmethyl)-2-methoxyphenol (EugOHNB).

6. The photosensitive composition of claim 1 wherein the diazo-quinone moiety is represented by formula (C), (D) or (E):

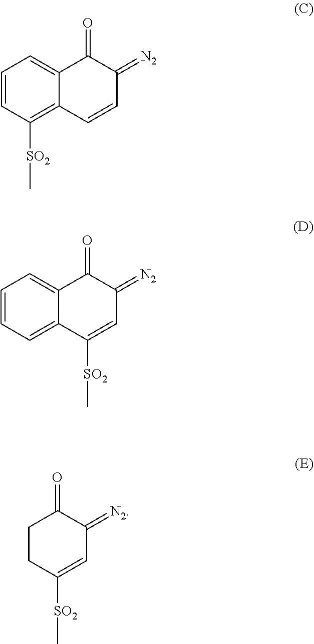

7. The photosensitive composition of claim 1 wherein the photo active compound is selected from one or more of the following: 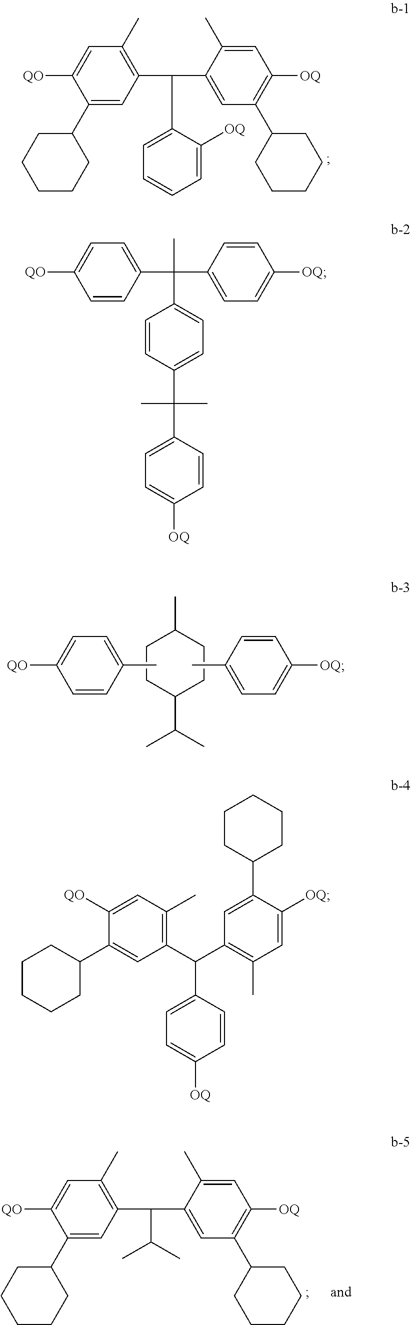 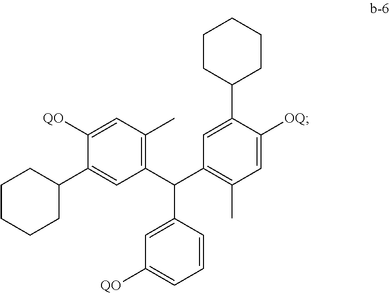
where at least one of Q is a group of the formula (C) or (D): 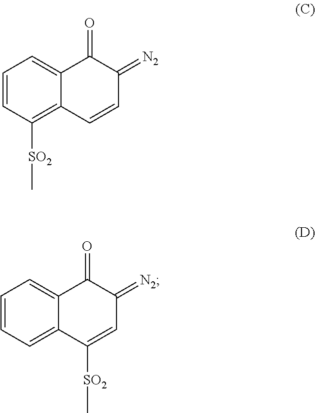
and
the remaining Q is hydrogen.

8. The photosensitive composition of claim 1 wherein the multifunctional crosslinking agent is selected from the group consisting of: 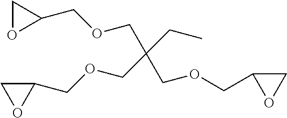 [SMILES: CCC(COCC1CO1)(COCC1CO1)COCC1CO1]
2,2′-(((2-ethyl-2-((oxiran-2-ylmethoxy)methyl)propane-1,3-diyl)bis(oxy))bis(methylene))bis(oxirane); also known as trimethylolpropane triglycidyl ether (from Nagase Chemtex, EX-321L); 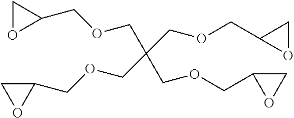 [SMILES: C(OCC(COCC1CO1)(COCC1CO1)COCC1CO1)C1CO1]
2,2′-(((2,2-bis((oxiran-2-ylmethoxy)methyl)propane-1,3-diyl)bis(oxy))bis(methylene))bis(oxirane); also known as pentaerythritol tetraglycidyl ether (PETG from Showa Denko); 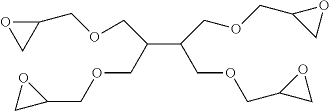 [SMILES: C(OCC(COCC1CO1)C(COCC1CO1)COCC1CO1)C1CO1]
2,2′-(((2-(1,3-bis(oxiran-2-ylmethoxy)propan-2-yl)propane-1,3-diyl)bis(oxy))bis(methylene))bis(oxirane); 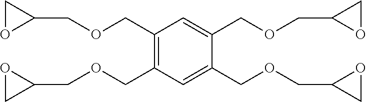 [SMILES: c1c(COCC2CO2)c(COCC2CO2)cc(COCC2CO2)c1COCC1CO1]
1,2,4,5-tetrakis((oxiran-2-ylmethoxy)methyl)benzene; and 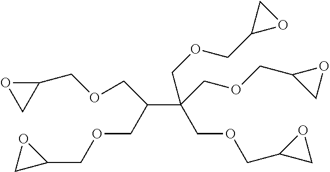 [SMILES: C(OCC(COCC1CO1)C(COCC1CO1)(COCC1CO1)COCC1CO1)C1CO1]
2,2′-(((2-(1,3-bis(oxiran-2-ylmethoxy)propan-2-yl)-2-((oxiran-2-ylmethoxy)methyl)propane-1,3-diyl)bis(oxy))bis(methylene))bis(oxirane).

9. The photosensitive composition of claim 1 further comprising a compound selected from the group consisting of a compound of formula (VIA) and a compound of formula (VIB): 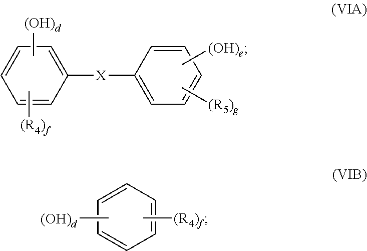
wherein d and e are integers from 1 to 4;
f and g are integers from 0 to 4;
X is selected from the group consisting of: a bond, —O—, —OCH₂O—, —OCH₂CH₂O—, —S—, —S—S—, —SO₂— and a group of formula —CR₂R₃—; where R₂ and R₃ are the same or different and independently of each other selected from hydrogen, methyl, ethyl, linear or branched C₃-C₆alkyl, C₃-C₈cycloalkyl, C₆-C₁₀aryl and C₇-C₁₂aralkyl; or
R₂ and R₃ taken together with the carbon atom to which they are attached form a 5 to 8 membered substituted or unsubstituted carbocyclic ring where said substituents are selected from C₁-C₈alkyl;
R₄ and R₅ are the same or different and independently of each other selected from hydrogen, —CO₂H, methyl, ethyl, linear or branched (C₃-C₆)alkyl, (C₃-C₈)cycloalkyl, (C₆-C₁₀)aryl and (C₇-C₁₂)aralkyl.

10. The photosensitive composition of claim 1 wherein the phenolic compound is selected from the group consisting of:

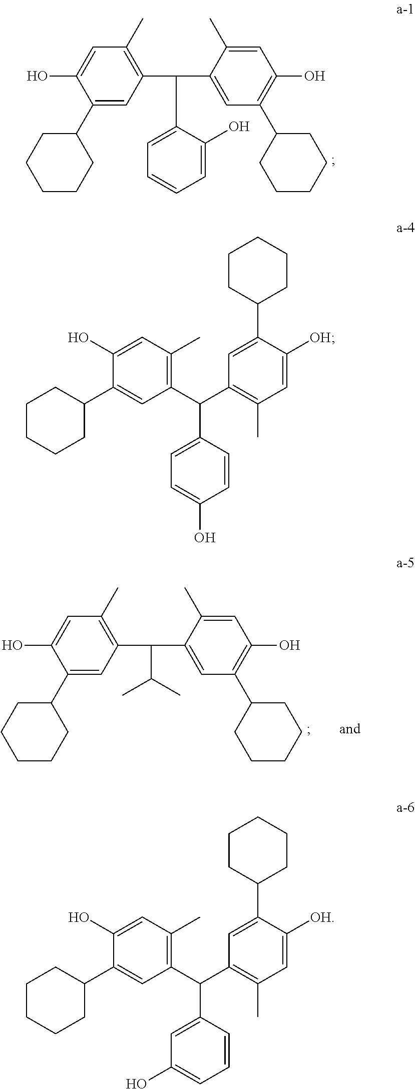 [SMILES: Cc1cc(O)c(C2CCCCC2)cc1C(c1cc(C2CCCCC2)c(O)cc1C)c1ccccc1O ; Cc1cc(O)c(C2CCCCC2)cc1C(c1ccc(O)cc1)c1cc(C2CCCCC2)c(O)cc1C ; Cc1cc(O)c(C2CCCCC2)cc1C(c1cc(C2CCCCC2)c(O)cc1C)C(C)C ; Cc1cc(O)c(C2CCCCC2)cc1C(c1cccc(O)c1)c1cc(C2CCCCC2)c(O)cc1C]

11. The photosensitive composition of claim 9 wherein a compound of formula (VIA) or a compound of formula (VIB) is selected from the group consisting of:
4-ethylresorcinol;
4-propylresorcinol;
4-butylresorcinol;
4-hexylresorcinol;
2-hydroxybenzoic acid;
3-hydroxybenzoic acid;
4-hydroxybenzoic acid;
4,4′-dihydroxydiphenyl sulfide;
3,3′-dihydroxydiphenyl disulfide;
4,4′-dihydroxydiphenyl disulfide;
4,4′-dihydroxydiphenyl sulfone;
2,2′-dihydroxydiphenyl ether;
4,4′-dihydroxydiphenyl ether;
biphenol;
2,2′-methylenediphenol (2,2′-dihydroxydiphenylmethane or o,o′-BPF);
4,4′-methylenediphenol;
2,2′-(ethane-1,1-diyl)diphenol;
4,4′-(ethane-1,1-diyl)diphenol;
2,2′-(propane-1,1-diyl)diphenol;
4,4′-(propane-1,1-diyl)diphenol;
2,2′-(propane-2,2-diyl)diphenol;
4,4′-(propane-2,2-diyl)diphenol;
4,4′-(1,3-dimethylbutylidene)diphenol;
2,2′-(4-methylpentane-2,2-diyl)diphenol;
4,4′-(4-methylpentane-2,2-diyl)diphenol;
4,4′-(2-ethylhexylidene)diphenol;
2,2′-(5-methylheptane-3,3-diyl)diphenol;
4,4′-(5-methylheptane-3,3-diyl)diphenol;
4,4′-ethylidenebisphenol;
2,2′-ethylenedioxydiphenol;
4,4′-(propane-2,2-diyl)bis(2-cyclohexylphenol);
4,4′-(2-methylpropane-1,1-diyl)bis(2-cyclohexyl-5-methylphenol);
5,5″-(cyclohexane-1,1-diyl)bis(([1,1′-biphenyl]-2-ol));
4,4′-(cyclohexane-1,1-diyl)bis(2-cyclohexylphenol);
4,4′-(4-methylcyclohexane-1,1-diyl)diphenol;
2-cyclohexyl-4-(2-(4-hydroxyphenyl)propan-2-yl)-5-methylphenol;
6,6′-methylenebis(2-(tert-butyl)-4-methylphenol);
6,6′-(2-methylpropane-1,1-diyl)bis(2,4-dimethylphenol);
4,4′-(2-methylpropane-1,1-diyl)bis(2-(tert-butyl)-5-methylphenol);
and mixtures in any combination thereof.

12. The photosensitive composition of claim 1 further comprising one or more compounds selected from the group consisting of: 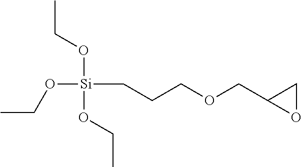 [SMILES: CCO[Si](CCCOCC1CO1)(OCC)OCC]
triethoxy(3-(oxiran-2-ylmethoxy)propyl)silane; 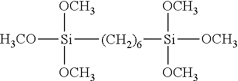
3,3,10,10-tetramethoxy-2,11-dioxa-3,10-disiladodecane; 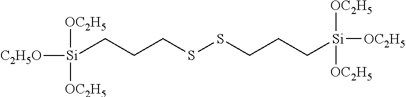
4,4,13,13-tetraethoxy-3,14-dioxa-8,9-dithia-4,13-disilahexadecane; 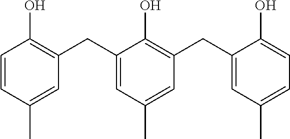 [SMILES: Cc1ccc(O)c(Cc2cc(C)cc(Cc3cc(C)ccc3O)c2O)c1]
2,2′-((2-hydroxy-5-methyl-1,3-phenylene)bis(methylene))bis(4-methylphenol); 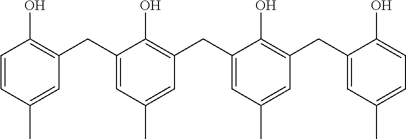 [SMILES: Cc1ccc(O)c(Cc2cc(C)cc(Cc3cc(C)cc(Cc4cc(C)ccc4O)c3O)c2O)c1]
6,6′-methylenebis(2-(2-hydroxy-5-methylbenzyl)-4-methylphenol); 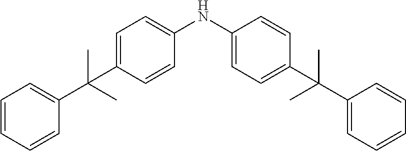 [SMILES: CC(C)(c1ccccc1)c1ccc(Nc2ccc(C(C)(C)c3ccccc3)cc2)cc1]
bis(4-(2-phenylpropan-2-yl)phenyl)amine; 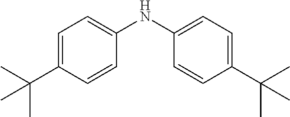 [SMILES: CC(C)(C)c1ccc(Nc2ccc(C(C)(C)C)cc2)cc1]
bis(4-(tert-butyl)phenyl)amine; 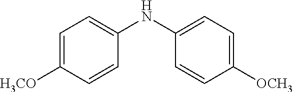 [SMILES: COc1ccc(Nc2ccc(OC)cc2)cc1]
bis(4-methoxyphenyl)amine; 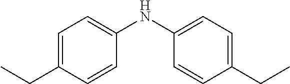 [SMILES: CCc1ccc(Nc2ccc(CC)cc2)cc1]
bis(4-ethylphenyl)amine;
and mixtures in any combination thereof.

13. A semiconductor or an optoelectronic device comprising a laminated semiconductor element or an adhesive element where said element consists of a photosensitive composition according to claim 1.

14. A semiconductor device comprising a chip stack structure where said chip stack structure further comprises a photosensitive composition according to claim 1.

15. A film comprising the composition of claim 1.

16. A microelectronic or optoelectronic device comprising one or more of a redistribution layer (RDL) structure, a chip-stack structure, a CMOS image sensor dam structure, where said structures further comprise a composition according to claim 1.

17. A method of forming a film for the fabrication of a microelectronic or optoelectronic device comprising:
coating a suitable substrate with a composition according to claim 1 to form a film;
patterning the film with a mask by exposing to a suitable radiation;
developing the film after exposure to form a photo-pattern; and
curing the film by heating to a suitable temperature.

18. The method of claim 17, where said developing is performed by an aqueous developer.

19. The method of claim 17, where the substrate is first hardbaked before said curing at a temperature of from 120° C. to 160° C. for 20 minutes to 60 minutes.

20. The method of claim 17, where said curing is performed at a temperature of from 150° C. to 200° C. at an incremental heating ramp of 5° C. and for 1 to 5 hours.
